(19) United States
(12) Patent Application Publication
(10) Pub. No.: US 2026/0262273 A1
(43) Pub. Date: Sep. 3, 2026

(54) GROUP III-N DEVICES WITH ETCH CONTROL LAYER AND METHODS OF MAKING THEREOF

(71) Applicant: TEXAS INSTRUMENTS INCORPORATED, Dallas, TX (US)

(72) Inventors: Jackson Bauer, Rowlett, TX (US); Zhikai Tang, Sunnyvale, CA (US); Karen Kirmse, Richardson, TX (US); Minjun Yan, Plano, TX (US); Chang Soo Suh, Allen, TX (US); Asad M. Haider, Plano, TX (US)

(21) Appl. No.: 19/068,381

(22) Filed: Mar. 3, 2025

(51) Int. Cl. H10D 64/01; H10D 30/01; H10D 30/47; H10D 62/85; H10D 64/27

(52) U.S. Cl. CPC H10D 64/01; H10D 30/015; H10D 30/475; H10D 62/8503; H10D 64/411

(57) ABSTRACT

Group III-N devices and methods including an etch control layer are disclosed, where the etch control layer is configured to facilitate a hybrid etch process for forming a gate contact aperture in a semiconductor device. In examples, a III-N gate stack is formed over a gate region of a substrate of the semiconductor device. An etch control layer is formed over the III-N gate stack. The hybrid etch process may include a dry etch stage that stops in the etch control layer, followed by a wet etch stage that stops on or in a III-N cap layer or a p-doped III-N layer of the III-N gate stack. A gate electrode is formed in the gate contact aperture, where the gate electrode may extend through the etch control layer, any intervening dielectric cap layers, and may contact the III-N cap layer or the p-doped III-N layer.

### CROSS-REFERENCE TO RELATED APPLICATION

This application is related to co-pending U.S. patent application Ser. No. ______, filed Mar. 3, 2025, and entitled “GROUP III-N DEVICES WITH ETCH CONTROL LAYER AND METHODS OF MAKING THEREOF,” which is hereby incorporated by reference in its entirety.

### FIELD OF THE DISCLOSURE

Disclosed implementations relate generally to the field of group III-N semiconductor devices and their fabrication.

### BACKGROUND

Group III nitride materials (also referred to as III-N materials) possess a unique combination of physical and electrical properties found to be beneficial in modern microelectronics and optoelectronics. Among these properties are wide bandgap, high saturated drift velocity and breakdown voltage, high thermal conductivity, robust chemical and thermal stability, etc. Due to these characteristics, III-N materials are being considered as promising materials for fabrication of powerful high-frequency transistors capable of functioning at high temperatures and in hostile environments. Whereas advances in III-N devices and their fabrication continue to grow apace, several lacunae remain, thereby requiring further innovation as will be set forth hereinbelow.

### SUMMARY

The following presents a simplified summary in order to provide a basic understanding of some examples of the present disclosure. This summary is not an extensive overview of the examples, and is neither intended to identify key or critical elements of the examples, nor to delineate the scope thereof. Rather, the primary purpose of the summary is to present some concepts of the present disclosure in a simplified form as a prelude to a more detailed description that is presented in subsequent sections further below.

In one example, a semiconductor device is disclosed which comprises a substrate including a source region, a gate region, a drain region, and an access region extending laterally from the gate region to the source and drain regions. The semiconductor device further comprises a III-N heterojunction structure over the substrate, the III-N heterojunction structure including a channel layer over the substrate and a barrier layer over the channel layer; a p-doped III-N layer over the barrier layer in the gate region; a III-N cap layer over the p-doped III-N layer; an etch control layer over at least a portion of the III-N cap layer, the etch control layer including a segment on the barrier layer in at least a portion of the access region; and a gate electrode extended through the etch control layer and contacting the III-N cap layer.

In one example, a method of fabricating a semiconductor device is disclosed. The method comprises forming a III-N heterojunction structure over a substrate, the III-N heterojunction structure including a channel layer over the substrate and a barrier layer over the channel layer; forming a p-doped III-N layer over the barrier layer; forming a III-N cap layer over the p-doped III-N layer; forming a III-N gate stack in a gate region of the substrate by removing the III-N cap layer and the p-doped III-N layer outside the gate region, the III-N gate stack including remaining portions of the III-N cap layer over the p-doped III-N layer; forming an etch control layer over the III-N gate stack, the etch control layer including a segment on the barrier layer in a source region, a drain region, and an access region of the substrate, the access region extending laterally from the gate region to the source region and the drain region; and forming a gate contact aperture over the III-N gate stack using a hybrid etch process including a dry etch stage followed by a wet etch stage that stops in or on the III-N cap layer.

In one example, a semiconductor device is disclosed which comprises a substrate including a source region, a gate region, a drain region, and an access region extending laterally from the gate region to the source and drain regions. The semiconductor device further comprises a III-N heterojunction structure over the substrate, the III-N heterojunction structure including a channel layer over the substrate and a barrier layer over the channel layer; a p-doped III-N layer over the barrier layer in the gate region; an etch control layer over at least a portion of the p-doped III-N layer, the etch control layer including a segment on the barrier layer in at least a portion of the access region; and a gate electrode extended through the etch control layer and contacting the p-doped III-N layer.

In one example, a method of fabricating a semiconductor device is disclosed. The method comprises forming a III-N heterojunction structure over a substrate, the III-N heterojunction structure including a channel layer over the substrate and a barrier layer over the channel layer; forming a p-doped III-N layer over the barrier layer; forming a III-N gate stack in a gate region of the substrate by removing the p-doped III-N layer outside the gate region, the III-N gate stack including a remaining portion of the p-doped III-N layer in the gate region; forming an etch control layer over the III-N gate stack, the etch control layer including a segment on the barrier layer in a source region, a drain region, and an access region of the substrate, the access region extending laterally from the gate region to the source region and the drain region; and forming a gate contact aperture over the III-N gate stack using a hybrid etch process including a dry etch stage followed by a wet etch stage that stops in or on the p-doped III-N layer.

In one example, a semiconductor device is disclosed which comprises a substrate including a source region, a gate region, a drain region, and an access region extending laterally from the gate region to the source and drain regions. The semiconductor device further comprises a III-N heterojunction structure over the substrate, the III-N heterojunction structure including a channel layer over the substrate and a barrier layer over the channel layer; a p-doped III-N layer over the barrier layer in the gate region; a first etch control layer over the p-doped III-N layer; a dielectric cap layer over the first etch control layer; and a second etch control layer over the dielectric cap layer, the second control layer including a segment directly on the barrier layer in at least a portion of the access region.

In one example, a method of fabricating a semiconductor device is disclosed. The method comprises forming a III-N heterojunction structure over a substrate, the III-N heterojunction structure including a channel layer over the substrate and a barrier layer over the channel layer; forming a p-doped III-N layer over the barrier layer; forming a first etch control layer over the p-doped III-N layer; forming a dielectric cap layer over the first etch control layer; forming a III-N gate stack in a gate region of the substrate by removing the dielectric cap layer, the first etch control layer and the p-doped III-N layer outside the gate region, the III-N gate stack including remaining portions of the dielectric cap layer and the first etch control layer over the p-doped III-N layer; forming a second etch control layer over the III-N gate stack, the second etch control layer including a segment on the barrier layer in a source region, a drain region, and an access region of the substrate, the access region extending laterally from the gate region to the source region and the drain region of the substrate; and forming a gate contact aperture over the III-N gate stack using a hybrid etch process including a dry etch stage followed by a wet etch stage that stops in or on the p-doped III-N layer.

In one example, a method of fabricating a semiconductor device is disclosed. The method comprises forming a III-N heterojunction structure over a substrate, the III-N heterojunction structure including a channel layer over the substrate and a barrier layer over the channel layer; forming a p-doped III-N layer over the barrier layer; forming a III-N cap layer over the p-doped III-N layer; forming a first etch control layer over the III-N cap layer; forming a dielectric cap layer over the first etch control layer; forming a III-N gate stack in a gate region of the substrate by removing the dielectric cap layer, the first etch control layer, the III-N cap layer and the p-doped III-N layer outside the gate region, the III-N gate stack including remaining portions of the dielectric cap layer, the first etch control layer and the III-N cap layer over the p-doped III-N layer; forming a second etch control layer over the III-N gate stack, the second etch control layer including a segment on the barrier layer in a source region, a drain region, and an access region of the substrate, the access region extending laterally from the gate region to the source region and the drain region of the substrate; and forming a gate contact aperture over the III-N gate stack using a hybrid etch process including a dry etch stage followed by a wet etch stage that stops in or on the III-N cap layer.

In one example, a semiconductor device is disclosed which comprises a substrate including a source region, a gate region, a drain region, and an access region extending laterally from the gate region to the source and drain regions. The semiconductor device further comprises a III-N heterojunction structure over the substrate, the III-N heterojunction structure including a channel layer over the substrate and a barrier layer over the channel layer; a p-doped III-N layer over the barrier layer in the gate region; a III-N cap layer over the p-doped III-N layer; an etch control layer over at least a portion of the III-N cap layer, the etch control layer confined to the gate region; and a gate electrode extended through the etch control layer and contacting the III-N cap layer.

In one example, a method of fabricating a semiconductor device is disclosed. The method comprises forming a III-N heterojunction structure over a substrate, the III-N heterojunction structure including a channel layer over the substrate and a barrier layer over the channel layer; forming a p-doped III-N layer over the barrier layer; forming a III-N cap layer over the p-doped III-N layer; forming an etch control layer over the III-N cap layer; forming a III-N gate stack in a gate region of the substrate by removing the etch control layer, the III-N cap layer and the p-doped III-N layer outside the gate region, the III-N gate stack including remaining portions of the etch control layer and the III-N cap layer over the p-doped III-N layer; and forming a gate contact aperture over the III-N gate stack using a hybrid etch process including a dry etch stage followed by a wet etch stage that stops in or on the III-N cap layer.

In one example, a semiconductor device is disclosed which comprises a substrate including a source region, a gate region, a drain region, and an access region extending laterally from the gate region to the source and drain regions. The semiconductor device further includes a III-N heterojunction structure over the substrate, the III-N heterojunction structure including a channel layer over the substrate and a barrier layer over the channel layer; a p-doped III-N layer over the barrier layer in the gate region; an etch control layer over at least a portion of the p-doped III-N layer, the etch control layer confined to the gate region; and a gate electrode extended through the etch control layer and contacting the p-doped III-N layer.

In one example, a method of fabricating a semiconductor device is disclosed. The method comprises forming a III-N heterojunction structure over a substrate, the III-N heterojunction structure including a channel layer over the substrate and a barrier layer over the channel layer; forming a p-doped III-N layer over the barrier layer; forming an etch control layer over the p-doped III-N layer; forming a III-N gate stack in a gate region of the substrate by removing the etch control layer and the p-doped III-N layer outside the gate region, the III-N gate stack including a remaining portion of the etch control layer over the p-doped III-N layer; and forming a gate contact aperture over the III-N gate stack using a hybrid etch process including a dry etch stage followed by a wet etch stage that stops in or on the p-doped III-N layer.

### BRIEF DESCRIPTION OF THE DRAWINGS

Implementations of the present disclosure are illustrated by way of example, and not by way of limitation, in the Figures of the accompanying drawings. Different references to “an” or “one” implementation in this disclosure are not necessarily to the same implementation, and such references may mean at least one. Further, when a particular feature, structure, or characteristic is described in connection with an implementation, such feature, structure, or characteristic in connection with other implementations may be feasible whether or not explicitly described.

The accompanying drawings are incorporated into and form a part of the specification to illustrate one or more example implementations of the present disclosure. Various advantages and features of the disclosure are described in the following Detailed Description taken in connection with the appended claims and with reference to the attached drawing Figures in which:

FIGS. 1A-1K depict cross-sectional views of a semiconductor device including a GaN device at various stages of a process flow including hybrid etch control for gate stack formation according to an example of the present disclosure;

FIG. 2 depicts a cross-sectional view of a semiconductor device including a gate stack according to one variation;

FIGS. 3A-3I depict cross-sectional views of a semiconductor device including a GaN device at various stages of a process flow including hybrid etch control for gate stack formation according to an example of the present disclosure;

FIGS. 4-12 depict cross-sectional views of semiconductor devices including gate stacks according to some variations;

FIGS. 13A-13K depict cross-sectional views of a semiconductor device including a GaN device at various stages of a process flow including hybrid etch control for gate stack formation according to an example of the present disclosure;

FIG. 14 depicts a cross-sectional view of a semiconductor device including a gate stack according to one variation;

FIGS. 15A-15I depict cross-sectional views of a semiconductor device including a GaN device at various stages of a process flow including hybrid etch control for gate stack formation according to an example of the present disclosure;

FIGS. 16-18 depict cross-sectional views of semiconductor devices including gate stacks according to some variations; and

FIG. 19 is a flowchart of a method according to some examples of the present disclosure.

### DETAILED DESCRIPTION

Examples of the disclosure are described with reference to the attached Figures where like reference numerals are generally utilized to refer to like elements. The Figures are not drawn to scale and they are provided merely to illustrate examples. Numerous specific details, relationships, and methods are set forth below to provide an understanding of one or more examples. However, some examples may be practiced without such specific details. In other instances, well-known subsystems, components, structures and techniques have not been shown in detail in order not to obscure the understanding of the examples. Accordingly, the examples of the present disclosure may be practiced without such specific components.

Additionally, terms such as “coupled” and “connected,” along with their derivatives, may be used in the following description, claims, or both. It should be understood that these terms are not necessarily intended as synonyms for each other. “Coupled” may be used to indicate that two or more elements, which may or may not be in direct physical or electrical contact with each other, co-operate or interact with each other. “Connected” may be used to indicate the establishment of communication, i.e., a communicative relationship, between two or more elements that are coupled with each other. Further, in one or more examples set forth herein, generally speaking, an element, component or module may be configured to perform a function if the element may be programmed for performing or otherwise structurally arranged to perform that function.

Without limitation, examples of the present disclosure will be set forth below in the context of improving performance characteristics of semiconductor devices based on Group III nitride materials, also referred to as III-N materials, such as gallium nitride (GaN) devices.

GaN devices, e.g., GaN transistors, provide certain performance advantages over silicon, including lower on-state resistance (e.g., drain-source resistance or R_{DSON}), lower switching losses, and improved breakdown voltage, among others. GaN transistors include a hetero epitaxy structure with a junction between materials of different bandgaps (e.g., a heterojunction structure), such as aluminum gallium nitride (AlGaN) and gallium nitride, to provide a 2-dimensional electron gas (2DEG) formed within the AlGaN/GaN hetero epitaxy structure that is used for device operation—e.g., forming a channel of the GaN device. The 2-dimensional electron gas (2DEG) may be referred to as a 2DEG channel. Depletion mode (DMODE) GaN transistors are normally on, whereas enhancement mode (EMODE) GaN transistors are normally off. In some examples, EMODE GaN transistors include a gate stack with a p-type doped gallium nitride (p-GaN) layer that depletes the 2DEG beneath the gate stack at zero or negative gate bias. In some examples, the p-GaN layer may comprise a GaN layer doped with magnesium (Mg) or other p-type dopants. Applying a positive gate voltage enhances the 2DEG under the gate and turns the EMODE GaN device on to allow current flow between the source and drain.

In some examples, a GaN device may be formed with one or more GaN layers epitaxially grown over a suitable substrate, e.g., including a silicon substrate. At least a portion of the GaN layers may form an epitaxial stack (or “epi” stack) operable as a III-N heterojunction structure over the substrate. In some implementations, a p-GaN layer may be provided over the heterojunction structure for effectuating EMODE device functionality. For example, a p-GaN layer having a suitable thickness and/or appropriate levels of p-type dopants may be provided in a gate region to control the threshold voltage (V_{T} or V_{TH}) and manage R_{DSON} performance of the GaN device. In general, higher threshold voltages are desired in order to reduce the likelihood of accidentally turning on an EMODE device, increase operational margins, reduce leakage current (e.g., off-state I_{DS}), etc.

Although p-doped III-N layers may be used in forming a suitable gate for controlling the channel characteristics of EMODE devices, the formation of III-N gates can be sensitive to process flow variation. Accordingly, a capping film (also referred to as a capping layer or a cap layer) may be used in some examples to protect the p-doped III-N gate from potential damage that may be caused due to plasma chemistry and/or temperatures used in processing. Because of the protective nature of the capping layer, even small variations in the capping layer can shift electrical characteristics, e.g., the threshold voltage (V_{T}), and correspondingly affect the performance of the device.

As such, there is little etch selectivity in current process flows between the capping layer, which may comprise an AlGaN layer, and the underlying p-doped III-N layer. Accordingly, gate contact formation including removal of a top portion of the capping layer while leaving a remaining portion with a desirable thickness in the gate stack requires tight process control. As a result, precision process equipment requiring high capital expenditures (capex) and/or operational expenditures (opex) may need to be deployed in a fabrication facility to manufacture reliable EMODE devices including p-GaN gates. Relatedly, additional inline metrology may be needed in order to ensure that the capping layer has a remaining thickness (e.g., after etch) that is within a tight tolerance. Deployment of inline metrological equipment may further increase manufacturing costs.

On the other hand, source/drain contact etch processing may not require a highly selective process in some example flows. Because of the differences in process sensitivity between source/drain (S/D) contact etch processing and p-GaN gate contact etch processing, separate process loops may be deployed in such flows. For example, two different pattern/etch/ash/clean loops may be implemented with respect to S/D contact etch processing and gate contact etch processing in a fabrication flow, which also adds cost, complexity, and cycle time to the process.

Examples of the present disclosure recognize the foregoing challenges and advantageously provide a hybrid etch integration solution where an etch stop or etch control (ES/EC) layer may be provided for separating gate contact etch processing into multiple stages having different etch selectivities. In some examples, a finishing stage having higher etch selectivity, e.g., a wet etch, may be implemented for achieving tight thickness control of a capping layer (e.g., an AlGaN cap layer) remaining in a p-GaN gate stack without requiring cost-prohibitive process control. In some examples, the ES/EC layer, which may be simply referred to as an EC layer for purposes of the present disclosure, may comprise an atomic layer deposition (ALD) film comprising aluminum oxide (Al₂O₃), aluminum nitride (AlN) and/or a combination thereof. In some examples, a finishing etch stage may comprise a wet etch having a high degree of selectivity between the EC film and the underlying AlGaN layer and/or p-doped III-N gate layer. As will be set forth below in detail, example hybrid etch solutions of the present disclosure may be integrated in a fabrication flow at various stages, e.g., depending on whether a gate first flow or a gate last flow is implemented. In still further examples, multiple EC layers may be provided where some EC layers may function as capping layers in a gate stack. In still further examples, S/D contact etch and p-GaN gate contact etch may be processed concurrently, thus obviating the need for separate process loops in a fabrication flow. Accordingly, additional cost savings may be realized in some examples of the present disclosure. Whereas the examples herein may provide various structures, materials and processes that may engender these and other beneficial effects, no particular result is a requirement unless explicitly recited in a particular claim.

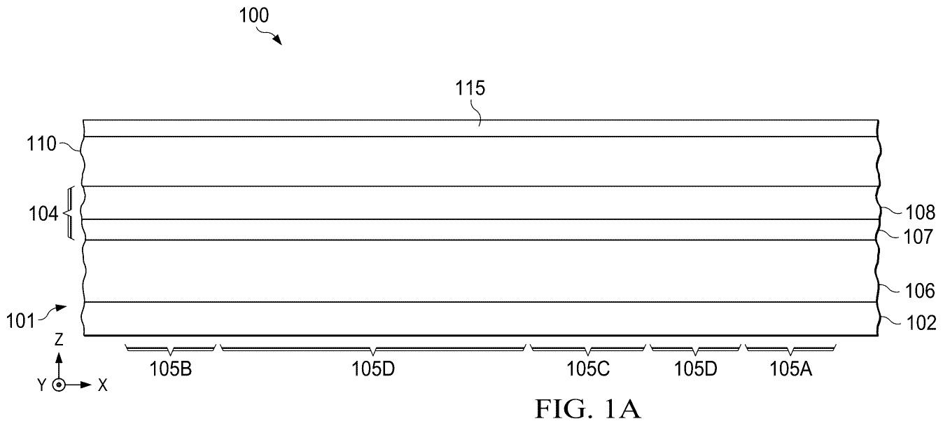

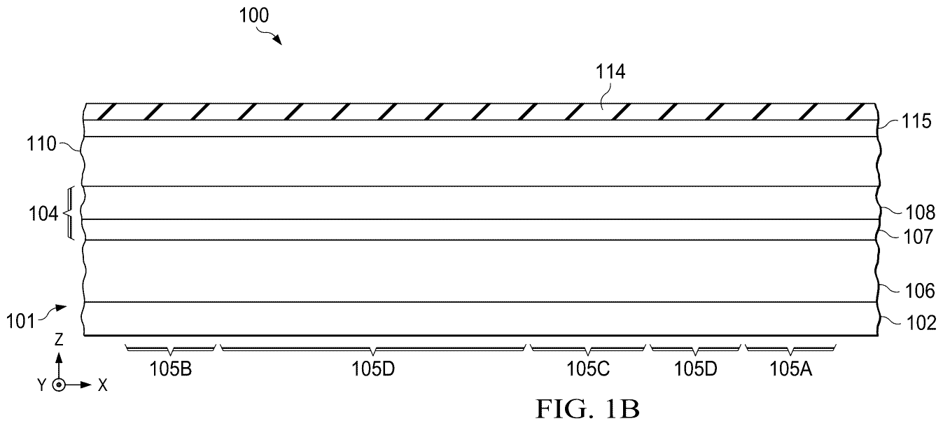

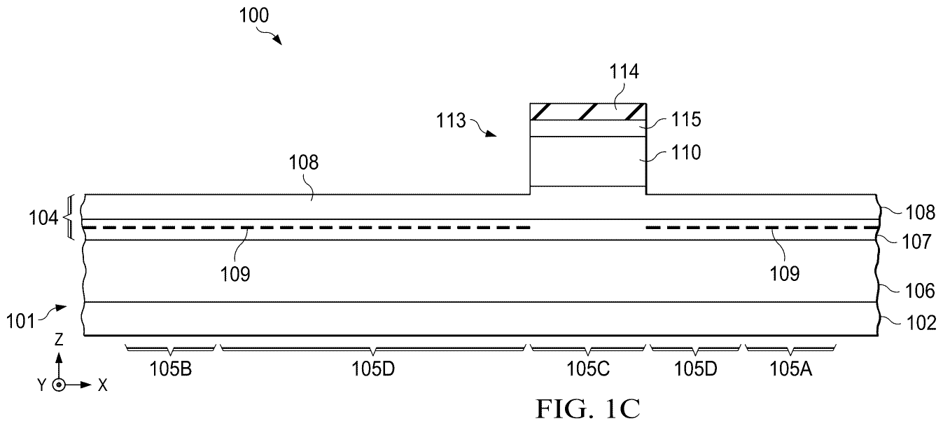

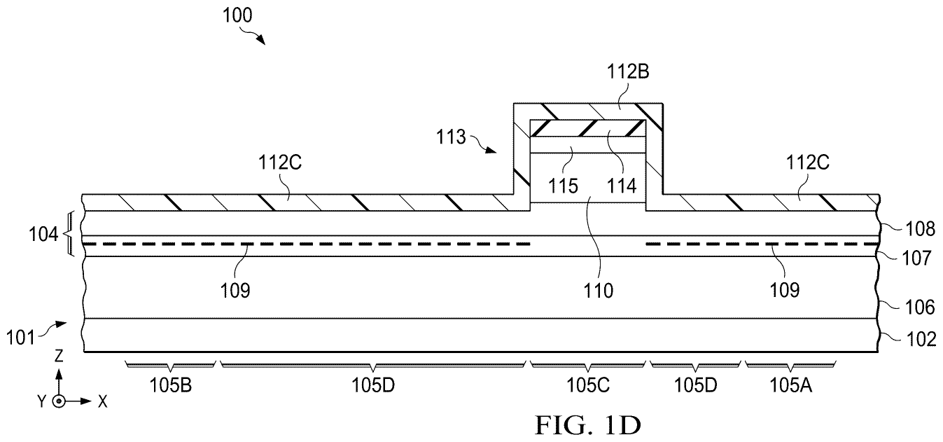

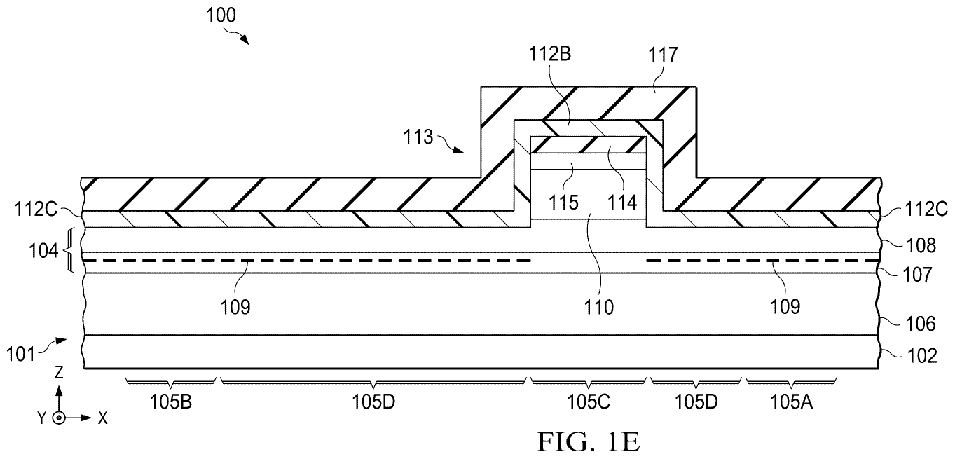

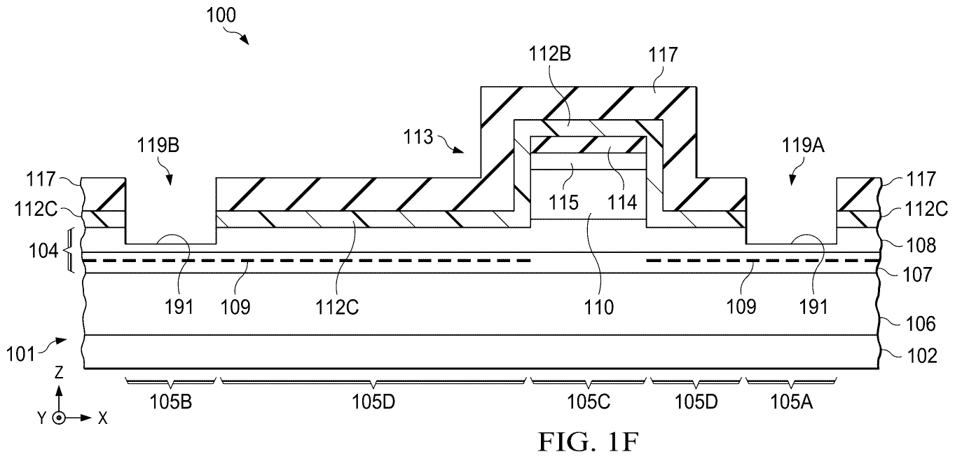

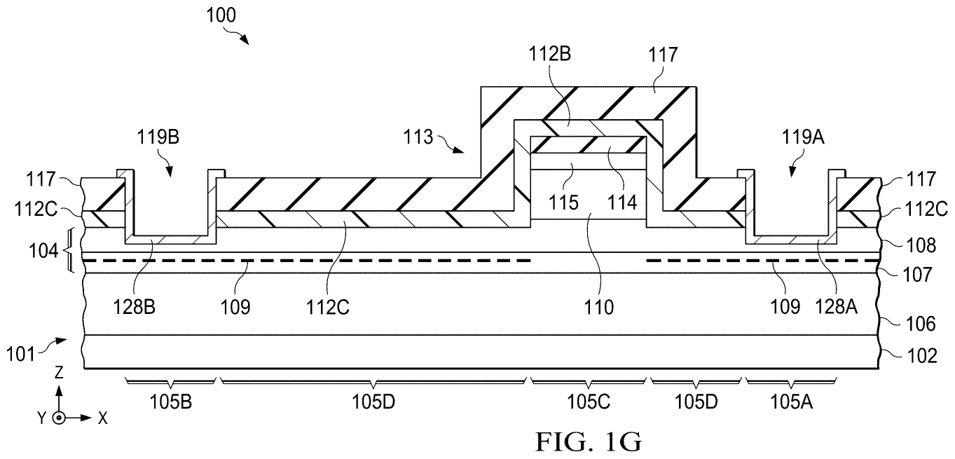

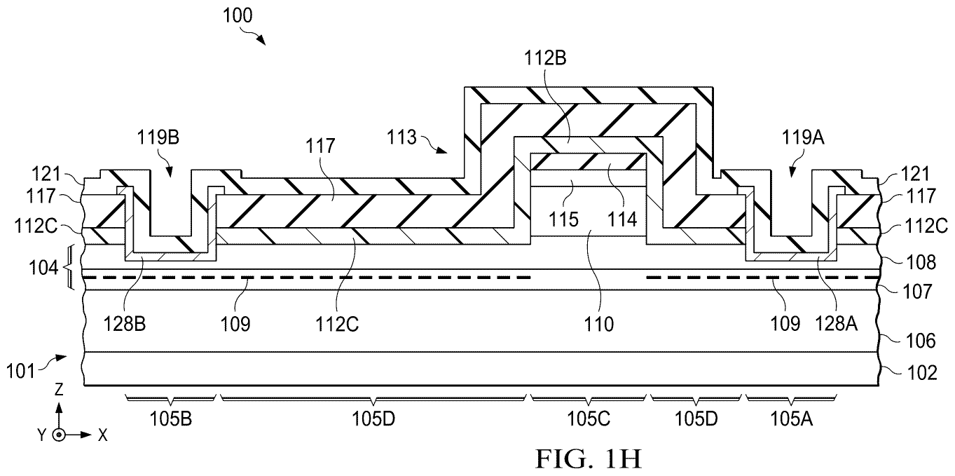

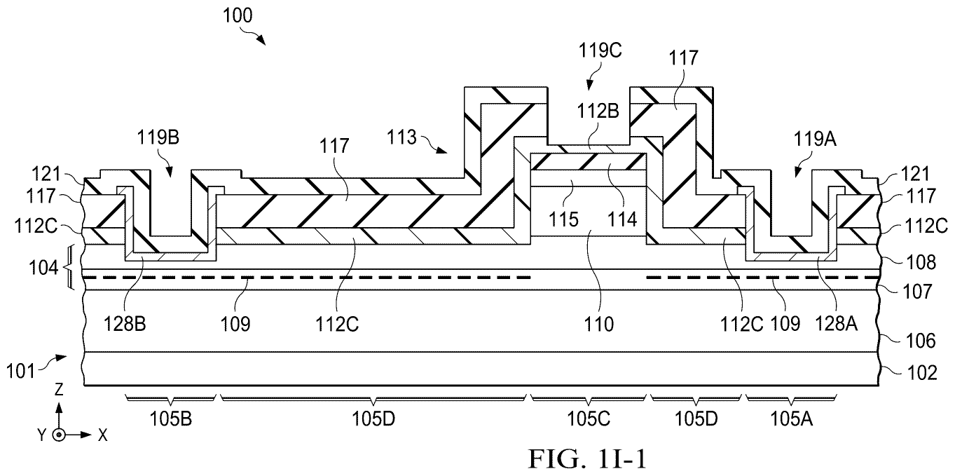

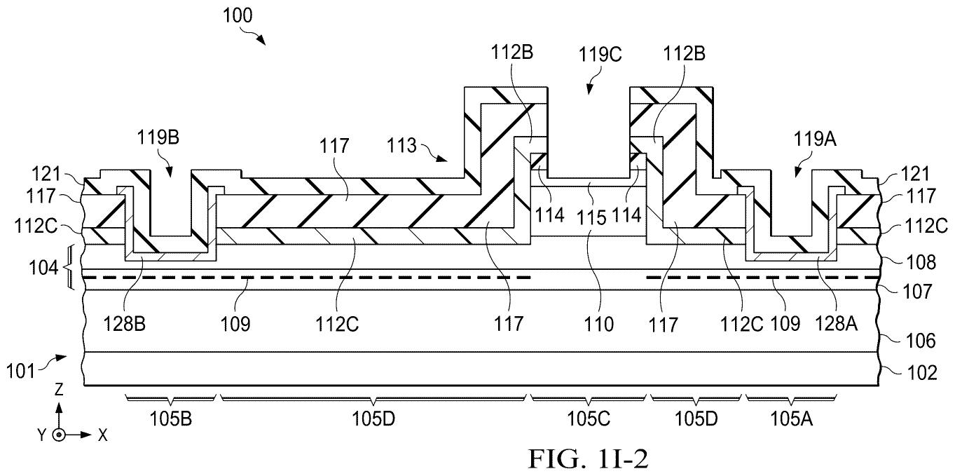

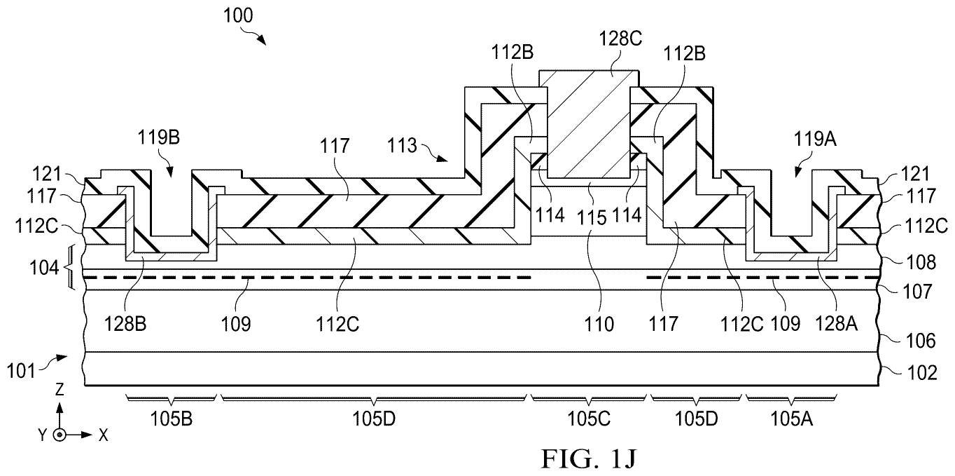

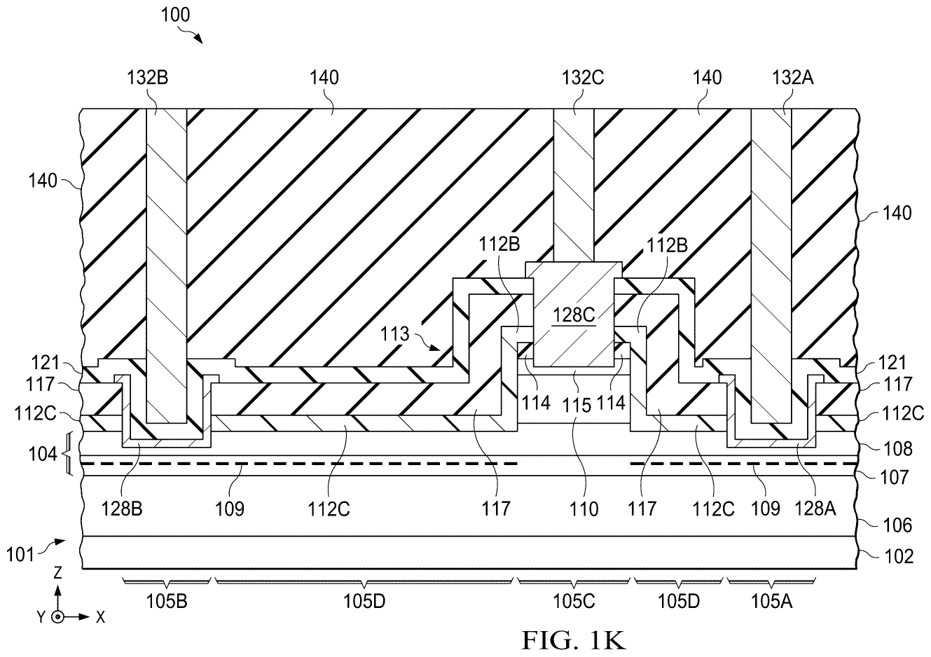

Referring to the drawings, FIGS. 1A-1K depict cross-sectional views of a semiconductor device 100 at various stages of a process flow including hybrid etch control for gate stack formation according to an example of the present disclosure. In this and other examples of the disclosure, an EC layer comprising a high bandgap dielectric material (e.g., a dielectric material with a bandgap energy greater than that of silicon oxide, a dielectric material with a bandgap energy greater than that of silicon nitride, etc.) such as Al₂O₃, AlN, and/or a combination thereof, may be deposited over source/drain (S/D) regions, access regions, as well as the gate region of a device before depositing other passivating films. In some arrangements, the EC layer may be operable to serve two purposes: (1) as a performance-enhancing film by increasing the density of charge carriers in a conductive channel, e.g., a 2DEG, of the device; and (2) as an etch stop/control layer for the p-GaN contact and S/D contact etches. In some arrangements, the EC film may be used as a sacrificial layer in the contact regions. A dry etch can be used as a first or initial removal stage to remove the passivating films, stopping in or on the EC film. A wet etch may be used as a second or final removal stage to remove the remaining EC film in the contact regions, where the wet etch may be implemented with a high selectivity with respect to the underlying layers of a gate stack, e.g., AlGaN and/or p-GaN films. The inclusion of a wet etch stage as a finishing stage according to the examples herein is beneficial, as the wet etch stage may improve process control by reducing the impact of etch rate variation as well as etcher-to-etcher variability with respect to the topology of critical gate structures/layers in a device. Accordingly, reliable EMODE devices may be manufactured in this manner with reduced capex/opex costs as noted previously.

FIG. 1A depicts an intermediate stage of the semiconductor device 100 formed on a portion of a substrate 102, where an example GaN epi growth stage is illustrated. Depending on implementation, the substrate 102 may be provided as a silicon wafer, a silicon-on-sapphire wafer, or a silicon carbide wafer, and/or as semiconductor substrates including cores configured for matching coefficient of thermal expansion (CTE), and/or the like. A buffer layer 106 comprising one or more layers of III-N semiconductor material, e.g., which may form a III-N stack or a GaN stack, is formed on the substrate 102. In some examples where the substrate 102 is implemented as a silicon wafer or a sapphire wafer, the buffer layer 106 may include a nucleation layer having a stoichiometry that includes aluminum to match a lattice constant of the substrate 102. In some examples, the buffer layer 106 may further include layers/sublayers of aluminum gallium nitride (AlGaN) with decreasing aluminum content. The buffer layer 106 may include an unintentionally doped (UID) GaN sublayer in some arrangements, which may support forming a conductive channel therein. For purposes of the examples herein, the various layers/sublayers of a buffer layer, e.g., the buffer layer 106, are not specifically shown in the Figures of the present disclosure.

Depending on implementation, the buffer layer 106 may have a thickness of about 1 micron (μm) to several microns, e.g., 3.5 μm to 7.0 μm, which may be formed by a suitable epitaxial process, e.g., a metal organic vapor phase epitaxy (MOVPE) process with several operations to form the various layers and/or sublayers. In some arrangements, an example buffer layer 106 may comprise a stack of multiple layers/sublayers of suitable materials and compositions (e.g., GaN, AlGaN, etc.) as noted above. In some arrangements, the layers/sublayers of the buffer layer 106 may have variable thicknesses depending on the technology and device application. In some arrangements, the buffer layer 106 may include AlGaN-based transition layers, epitaxial layers with strain-layer superlattice (SLS) structures, and the like.

The buffer layer 106 may be formed as part of an epitaxial III-N stack over the substrate 102. In some examples, a channel layer 107 may be regarded as formed over the buffer layer 106—e.g., over a top portion of the buffer layer 106—as depicted in FIG. 1A. In some examples, a channel layer 107 may be regarded as part of the buffer layer 106. The channel layer 107 in conjunction with a barrier layer 108 formed over the channel layer 107 may be referred to as a III-N heterojunction structure 104. The III-N heterojunction structure 104 is configured or established to support a conductive channel (e.g., a 2DEG or 2D hole gas (2DHG)) in the channel layer 107. For purposes herein, the term “2DEG” may also include or refer to a 2DHG unless otherwise noted. Whereas a channel layer 107 may primarily include GaN material, there may be optional trace amounts of other group III elements, such as aluminum or indium, in some implementations. A barrier layer 108 comprising III-N semiconductor material and suitable thickness is formed over the channel layer 107. In an example arrangement, the barrier layer 108 may have a thickness ranging from about 1 nanometer (nm) to about 60 nm, and may include aluminum and nitrogen. In some versions of this example, the barrier layer 108 may include gallium at a lower atomic percent than aluminum. In some versions of this example, the barrier layer 108 may include gallium at a higher atomic percent than aluminum. In some versions, the barrier layer 108 may also include indium. In some examples, the barrier layer 108 includes an AlGaN layer.

Barrier layer 108 over the channel layer 107 is operable as part of a heterojunction structure, e.g., III-N heterojunction structure 104, for causing the formation of a 2DEG (e.g., 2DEG 109 shown in FIG. 1C) in the channel layer 107 proximate to an interface between the barrier layer 108 and the channel layer 107. In some examples, the stoichiometry and thickness of the barrier layer 108 may be configured to provide a suitable free charge carrier density (e.g., 3×10¹² cm⁻² to 2×10¹³ cm⁻²) of the 2DEG for facilitating the device operation.

For purposes of effectuating EMODE functionality, a p-doped III-N layer 110, e.g., comprising one or more layers of III-N material, is formed over the barrier layer 108 as shown in FIG. 1A. In some examples, the p-doped III-N layer 110 may also be referred to as a p-III-N layer or a p-GaN layer. In versions of this example, the p-doped III-N layer 110 may comprise a GaN layer doped with magnesium (Mg) or other suitable p-type dopants. In some examples, the p-doped GaN layer 110 may include a p-dopant concentration of about 1×10¹⁷ atoms/cm³ to 1×10²¹ atoms/cm³ and may have a thickness of about 10 nm to 200 nm.

In some examples, a III-N cap layer 115 may be formed over the p-GaN layer 110 in order to protect a p-GaN gate patterned from the p-GaN layer 110 in subsequent steps. In one implementation, the III-N cap layer 115 may comprise an undoped III-N layer such as an AlGaN cap layer having an initial thickness of about 3 nm to 10 nm, which may be partially removed in a gate contact formation stage using a hybrid etch process as will set forth below.

For purposes of the present disclosure, the semiconductor device 100 may include a III-N device, e.g., a GaN transistor 101, which may be formed in a device area of the substrate 102 surrounded by an isolation region. The device area may also be referred to as an active area. The device area may include different regions of the GaN device 101 such as a source region 105A, a drain region 105B, a gate region 105C, an access region 105D laterally extending from the gate region 105C to the source and drain regions 105A, 105B, respectively. As illustrated, the access region 105D includes a drain access region between the gate region 105C and the drain region 105B as well as a source access region between the gate region 105C and the source region 105A. As will be set forth further below, a gate stack may be formed in the gate region 105C which may be asymmetrically disposed in the device area relative to the source region 105A (where a source electrode or contact is to be formed) and the drain region 105B (where a drain electrode or contact is to be formed) although it is not a requirement. For example, there may be a greater lateral distance (e.g., along or parallel to the X-axis) between the gate region 105C and the drain region 105B (i.e., the drain access region) than a lateral distance (e.g., along or parallel to the X-axis) between the gate region 105C and the source region 105A (i.e., the source access region) in some implementations.

FIG. 1B illustrates a stage where a dielectric cap layer 114 is formed over the III-N cap layer 115 in some example arrangements. In some versions, the dielectric cap layer 114, where provided, may be used for protecting the III-N cap layer 115 and/or the p-GaN layer 110. In one example, the dielectric cap layer 114 may comprise a low-pressure chemical vapor deposition (LPCVD) silicon nitride (SiN) having a thickness ranging from about 10 nm to about 15 nm. In one example, the dielectric cap layer 114 may be formed by a high temperature LPCVD process, e.g., at temperatures ranging from about 700° C. to about 850° C., using suitable precursors such as dichlorosilane (DCS) and ammonia (NH₃). In some arrangements, a frontside clean and/or a backside clean (e.g., including wet/dry chemical clean, spray clean, etc.) may be implemented at this stage of fabrication.

FIG. 1C illustrates a stage where a gate etch process is performed for patterning a p-GaN gate as part of a gate stack 113 including a gate electrode (e.g., gate electrode 128C shown in FIG. 1J) in the gate region 105C. In the examples herein, gate stack 113 may also be referred to as a III-N gate stack or p-GaN gate stack. In an example arrangement, a dry etch process may be performed using a suitable etch mask (not shown in FIG. 1C) covering the gate region 105C. The etch process may remove portions of the dielectric cap layer 114, the III-N cap layer 115 and the p-GaN layer 110 from the S/D regions 105A/105B, as well as respective access regions 105D, and may stop in or on the barrier layer 108. As a result of patterning the p-GaN layer 110 (e.g., removing portions of the p-GaN layer 110 outside the gate region 105C), the 2DEG 109 may be formed in the channel layer 107 outside the gate region 105C as illustrated in FIG. 1C. Moreover, the 2DEG 109 remains reduced-e.g., absent in some cases, in the gate region 105C to effectuate the normally off EMODE functionality.

Although not specifically shown in FIG. 1C, a suitable device isolation step may be implemented to achieve isolation with respect to the GaN device 101. Depending on implementation, an isolation step may include mesa etching, implanting, etc., to define a region, where the 2DEG 109 outside the active area is absent, eliminated or otherwise disrupted. In one example, an isolation implant can be performed after the gate etch process-e.g., to electrically isolate the GaN device 101. In some arrangements, an isolation implant having an energy of between 100 kilo-electron volts (keV) and 300 keV with an implant dose of 1×10¹⁴ ions/cm² to 1×10¹⁶ ions/cm² may be implemented to achieve device isolation. In some arrangements, the implant species may comprise argon, silicon, fluorine, nitrogen, etc. Other implant species and implant energies are within the scope of the examples herein.

In one particular implementation, the isolation implant may include a 120 keV, 5×10¹⁴ atoms/cm² dose of Ar+ that destroys or otherwise prevents the formation of the 2DEG 109 in implanted regions by causing physical damage to the crystallinity of the heterojunction structure 104.

FIG. 1D illustrates a stage where an etch control (EC) layer 112B is deposited over the gate stack 113 and barrier layer 108. As noted previously, the EC layer 112B may also be referred to as an etch stop (ES) layer. In an example arrangement, a blanket deposition process may be performed to form the EC layer 112B over (e.g., conformally over) the topology of the gate stack 113 along the sidewalls thereof. As illustrated, the EC layer 112B includes a horizontal portion or segment 112C, referred to herein as an EC layer segment, that extends laterally over the barrier layer 108 across the S/D access regions 105D as well as S/D regions 105A/105B. In one example, the deposition process may comprise an ALD process that forms the EC layer 112B having a thickness of about 5 nm to 15 nm. Depending on implementation, the EC layer 112B may comprise a high bandgap material such as aluminum oxide (Al₂O₃), aluminum nitride (AlN) and/or a combination thereof. In additional and/or alternative embodiments, the EC layer 112B may comprise one or more of SiO₂, HfO₂, ZrO₂, Ta₂O₅, TiO₂, La₂O₃, BaO, Sc₂O₃, Y₂O₃, Lu₂O₃, Nb₂O₅, AlN, ZrN, HfN, and Si₃N₄. In some arrangements, the deposition process may be configured to deposit one or more layers or sublayers of a composite film forming a multilayer film stack. In still further examples, the deposition process may be configured to deposit one or more of a HfₓZr₁₋ₓO₂ composite film, an AlN/Al₂O₃ film stack, and an SiO₂/HfO₂ film stack, etc. Accordingly, for purposes of the present disclosure, the EC layer 112B may comprise any suitable material with a bandgap greater than 5 eV and exhibiting a high degree of etch selectivity with respect to an underlying layer (e.g., III-N cap layers, p-GaN layers, and any dielectric cap layers, etc.) into which an etch stage may be landed during contact aperture formation according to some examples herein. Furthermore, although ALD processing is illustrated in some examples with respect to forming high bandgap films, processes such as atomic layer epitaxy (ALE), physical vapor deposition (PVD), etc. are also within the scope of the present disclosure.

In an example implementation, the EC layer 112B may be deposited using a suitable ALD process depending on the material composition. For example, an AlN layer may be deposited using ALD at a temperature ranging from about 250° C. to about 350° C. with ammonia (NH₃) and trimethylaluminum (TMA) as precursors. In some examples, an Al₂O₃ layer may be deposited using ALD at similar temperatures, e.g. ranging from about 250° C. to about 350° C., using ozone (O₃) or water (H₂O) in combination with TMA as precursors.

FIG. 1E illustrates a stage where a dielectric layer 117 is formed over the EC layer 112B of the semiconductor device 100. In some examples, the dielectric layer 117 may be operable as a passivation layer. In some examples, the dielectric layer 117 may comprise an LPCVD SiN layer having a thickness of about 100 nm to 200 nm. For purposes of some examples herein, the dielectric layer 117 may be referred to as a first dielectric layer, and may be formed in an LPCVD process similar to the LPCVD process set forth above.

FIG. 1F illustrates a stage where S/D contact apertures 119A, 119B are formed in the source and drain regions 105A, 105B, respectively, using a hybrid etch process in an example gate last flow (e.g., where S/D electrodes are formed before forming a gate electrode). The contact apertures 119A/119B may be formed by etching or removing the material from the dielectric layer 117, EC layer segment 112C as well as a portion of the heterojunction structure 104 in a sequence of etch stages. In an example arrangement, a contact mask and pattern etch process may be used where the processing may comprise at least two etch stages including wet etch and dry etch processes in a particular etch sequence as part of a hybrid etch process. In versions of this or other examples, the hybrid etch process for forming S/D contact apertures 119A, 119B may include a two-stage etch process where a first stage including a dry etch process may precede a second stage including a wet etch process.

Depending on implementation, dry etch processes used in a hybrid etch process for forming S/D contact apertures may include inductively-coupled plasma (ICP) etch processes, deep reactive ion etching (DRIE) processes, high aspect ratio etch (HARE) processes, etc., without limitation, using suitable chemistries and process recipes. An example dry etch process may be configured to remove the dielectric layer 117 and a top portion of the horizontal segment 112C of the EC layer 112B, resulting in partially formed contact apertures having a bottom landing in the horizontal segment 112C overlying the barrier layer 108 in the S/D regions 105A, 105B.

A wet etch process having a high degree of selectivity (e.g., based on differential etch rates) between the materials of the EC layer 112B and the barrier layer 108, respectively, is performed after a suitable dry etch process to further extend the bottom of the contact apertures 119A/119B. In some examples, the wet etch process may be configured such that the contact apertures 119A/119B may have a bottom 191 formed in the barrier layer 108 as shown in FIG. 1F. In some additional and/or alternative examples, the contact apertures 119A/119B may extend through the barrier layer 108 and land at a depth into the channel layer 107. In further examples, the contact apertures 119A/119B may not extend into or through the barrier layer 108. Instead, the contact apertures 119A/119B may terminate on a top surface of the barrier layer 108 (e.g., without removal of material). Whereas contact apertures extending into the barrier layer 108 or the channel/buffer layer 107/106 may be implemented in forming “semi-recessed” or “recessed” contacts (e.g., with respect to the upper surface of the barrier layer 108 facing away from the channel layer 107) at a subsequent metallization step, contact apertures that land on the barrier layer 108 may be implemented in forming “no-recess” contacts according to some examples herein.

Various etch chemistries and/or process recipes may be used for performing a wet etch stage as part of a hybrid etch scheme or flow of the present disclosure. As will be set forth below, a wet etch stage may comprise a second etch stage or a finishing etch stage of a hybrid etch flow according to some examples. A non-exhaustive list of etch chemistries that may be used in an example flow may comprise hydrofluoric acid (HF), buffered oxide etch (BOE) or buffered hydrofluoric acid (BHF), Standard Clean-1 (SC-1), RCA Clean including SC-1 and SC-2, tetra-methyl ammonium hydroxide (TMAH), etc. Depending on the material compositions of the EC layer 112B, any intervening dielectric layers, and the barrier layer 108, etc., appropriate etch chemistries may be implemented according to the examples herein.

FIG. 1G illustrates a stage where S/D electrodes 128A/128B are formed in the contact apertures 119A/119B using a suitable contact metallization and anneal process. In an example arrangement, an initial metal layer (e.g., a MET0, M0 or Metal 0 layer) of a multi-level metal interconnect scheme may be used for forming the S/D electrodes 128A/128B. In one example, a metal deposition and etching process is performed that forms the conductive metal S/D electrodes 128A, 128B including vertical liners along the sidewalls of the contact apertures 119A/119B. In one example, the S/D electrodes 128A/128B may include one or more metals such as titanium (Ti), aluminum (Al), and/or copper (Cu). In one example, the S/D electrodes 128A/128B may comprise a Ti layer having a thickness of approximately 0.02 μm to 0.04 μm and a layer of AlCu alloy having a thickness of approximately 0.1 μm to 0.15 μm formed on the Ti layer. In some examples, the contact metallization process may include one or more metal layer depositions followed by patterning, etching, and cleaning and (optional) annealing (e.g., at a temperature of approximately 700° C. to 800° C. for approximately 20 to 45 seconds). For purposes herein, the S/D electrodes 128A/128B may also be referred to as S/D contacts in some examples.

In some additional and/or alternative arrangements, the S/D electrodes 128A/128B may comprise other refractory metals such as at least one of nickel (Ni), tungsten (W), tantalum (Ta), niobium (Nb), cobalt (Co), platinum (Pt), molybdenum (Mo), rhenium (Re), vanadium (V), zirconium (Zr), hafnium (Hf), ruthenium (Ru), and iridium (Ir), and/or in combination with a nitride of the refractory metal (e.g., Ti/TiN). In an example implementation, refractory metal layers and/or bulk conductive layers (e.g., comprising an AlCu alloy of 0.5% Cu) of the S/D electrodes 128A/128B may be formed using a sputter process, a reactive sputter process, or an ALD process.

FIG. 1H illustrates a stage where another dielectric layer, e.g., a second dielectric layer 121, is formed over the first dielectric layer 117 in the gate region 105C as well as the access regions 105D. In an example arrangement, the second dielectric layer 121 may extend (e.g., conformally extend) over the conductive sidewalls of the S/D electrodes 128A/128B in the S/D regions 105A/105B. In an example arrangement, the second dielectric layer 121 may comprise a plasma enhanced CVD (PECVD) layer of SiN material having a thickness of about 70 nm to 85 nm.

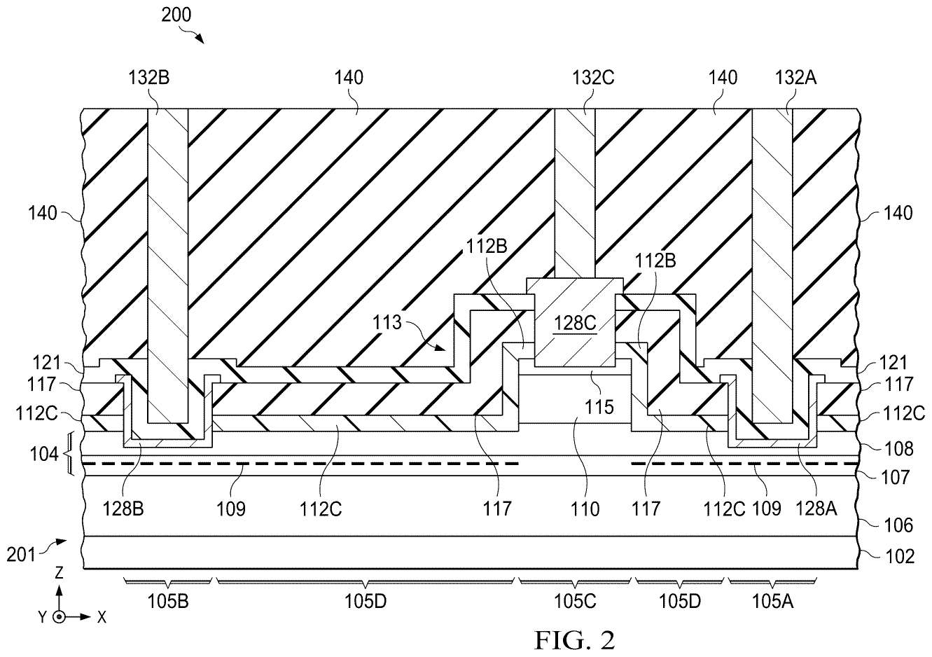

FIGS. 1I-1 and 1I-2 illustrate a flow where a gate contact aperture 119C is formed in the gate stack 113 using a hybrid etch process according to the present disclosure. In an example arrangement, the hybrid etch process for forming the gate contact aperture 119C may include aspects of the hybrid etch process set forth above for forming the S/D contact apertures 119A/119B. Accordingly, a gate contact mask and pattern etch process may be used for forming the gate contact aperture 119C where the processing may comprise a first etch stage including a dry etch may be followed by one or more wet etch stages depending on the composition of the layers disposed between the EC layer 112B and the III-N cap layer 115.

In some arrangements, dry etch processes used in forming the gate contact aperture 119C may include ICP etch processes, DRIE processes, HARE processes, etc., depending on implementation, as noted above. An example dry etch process may be configured to remove material from the first and second dielectric layers 117, 121 and a top portion of the EC layer 112B in the gate stack 113, resulting in partially formed gate contact aperture landing in the EC layer 112B overlying the dielectric cap layer 114 as illustrated in FIG. 1I-1.

In some arrangements, a single wet etch process or a combination of wet etch processes having appropriate selectivities (e.g., based on differential etch rates) between the materials of the EC layer 112B, dielectric cap layer 114, and the III-N cap layer 115, respectively, may be performed after a dry etch stage. Such a process may be configured to consume the remaining portion of the EC layer 112B, the dielectric cap layer 114 and extend the gate contact aperture 119C to a suitable depth into the III-N cap layer 115 in a controllable manner, as illustrated in FIG. 1I-2. Accordingly, the remaining portion of the III-N cap layer 115 overlying the p-GaN layer 110 in the gate stack 113 may be fabricated with a desirable thickness having requisite tight process control. Similar to the S/D contact etch flow set forth above, a non-exhaustive list of wet etch chemistries that may be used in an example gate contact etch flow may comprise HF, BOE/BHF, SC-1/SC-2, TMAH, and the like.

Some additional and/or alternative arrangements may include a hybrid etch flow where a wet etch stage may be configured to land on the III-N cap layer (where included) in a gate stack consuming little or no III-N cap material in the formation of a gate contact aperture. In other words, a wet etch stage may be configured to stop on a top surface of the III-N cap layer in some arrangements. For example, such a scenario may be obtained where the III-N cap layer has an initial thickness that is within a given range, thus obviating the need for removal from the III-N cap layer.

In some arrangements, a first wet etch having a first wet etch chemistry may be used for removing the remaining EC layer 112B and land in the dielectric cap layer 114. Thereafter, a second wet etch having a second wet etch chemistry different than the first wet etch chemistry may be used as a finishing etch stage to remove remaining material from the dielectric cap layer 114 and land on or in the III-N cap layer 115 with controllability in order to obtain the desired thickness. Depending on implementation, a wet etch comprising SC1 may be used to remove a remaining portion 121 of the EC layer 112B, which may be followed by a wet etch comprising BHF for removing the dielectric cap layer 114 in some examples. Thereafter, a suitable dopant activation anneal may be performed to activate the dopants in the p-GaN layer 110 in some arrangements.

FIG. 1J illustrates a stage where a gate electrode 128C is formed in the gate contact aperture 119C using a suitable gate metal mask and etch process. In some arrangements, the gate electrode 128C may comprise metal layers/sublayers similar to the metal layers/sublayers of the S/D electrodes 128A/128B. In other arrangements, the gate electrode 128C may comprise metal layers/sublayers different from the metal layers/sublayers of the S/D electrodes 128A/128B. In one example, gate metallization may include depositing a suitable conductive metal to fill the gate contact aperture 119C with a suitable overburden thickness (e.g., approximately 0.15 μm to 0.20 μm), forming a gate metal mask thereover with appropriate patterning, and etching the gate metal layer to form the gate electrode 128C. In an example, the gate electrode 128C may comprise one or more metals such as Ti, Ni, W, Pt, Ir, Al, Au, etc., including alloys thereof, as well as metallic nitrides such as titanium nitride (TiN), tantalum nitride (TaN) and the like.

FIG. 1K depicts a more completely formed semiconductor device 100 including the GaN device 101. As depicted, suitable source and drain terminals 132A, 132B as well as a gate terminal 132C may be formed for making electrical contact with respective electrodes 128A-128C through an insulator stack 140, e.g., comprising an inter-level dielectric (ILD) and/or pre-metal dielectric (PMD) insulator layer. In some arrangements, terminals 132A-132C may be formed from a further metal layer or level (e.g., a MET1, M1 or Metal 1 layer) having appropriate metal compositions.

Whereas the foregoing example is illustrative of a hybrid etch scheme integrated in a gate last flow (e.g., where S/D electrodes are formed before forming a gate stack including the gate electrode), additional and/or alternative examples of the present disclosure may include integration of a hybrid etch scheme in a gate first flow (e.g., where S/D electrodes are formed after forming the gate electrode). For example, a gate first flow implementation including a hybrid etch scheme may include reversing the sequences of the S/D electrode formation (shown in FIGS. 1F-1G) and the gate electrode formation (shown in FIGS. 1I-1J) so as to obtain a final device structure substantially similar to the structure of the semiconductor device 100 shown in FIG. 1K.

As the process loops for S/D electrode and gate electrode formation may be performed separately in an example flow, e.g., using two masks for S/D electrode formation and two masks for gate electrode formation, the S/D electrodes 128A/128B may be formed with a different metal than a metal used for forming the gate electrode 128C in some examples, although it is not a requirement. Where two separate process loops are provided for forming S/D and gate electrodes, respective hybrid etch stages or processes may be referred to as first and second hybrid etch stages or processes without limitation as to any particular order or sequence.

In some additional and/or alternative examples, S/D contact etch and gate contact etch stages may each include two different types of hybrid etch schemes. In some additional and/or alternative examples, only the gate etch loop may include a hybrid etch scheme while the S/D contact etch loop may include a single etch stage, e.g., a dry etch. In some additional and/or alternative examples, one or more of the cap layers of a gate stack may be omitted and/or replaced in a flow including a hybrid etch process. In still further examples, multiple ALD/ALE/PVD layers (collectively referred to as “ALD” layers) may be provided where some layers may function as EC layers while other layers may function as capping layers in a gate stack. In still further examples, S/D contact etch and gate contact etch stages may be processed concurrently, as noted previously. Moreover, some examples may include depositing an EC layer before forming a gate stack. Depending on implementation, a number of process flows may therefore be realized that may include several permutations and/or combinations of the foregoing variations according to the teachings of the present disclosure. Set forth below are at least a subset of these and other examples in additional detail without necessarily limiting the scope of the present disclosure.

In one example, a dielectric cap layer, e.g., the dielectric cap layer 114, may be omitted from a gate stack such as the gate stack 113 described above in respect of the process flow shown in FIGS. 1A-1K. Accordingly, a semiconductor device 200 including a GaN device 201 may be obtained in such a flow where the dielectric cap layer 114 is absent from the gate stack 113 as shown in FIG. 2. In this example, the contact apertures 119A/119B may be formed by removing the material from the dielectric layer 117, EC layer segment 112C as well as a portion of the heterojunction structure 104 in a similar manner as set forth above. As before, the contact apertures 119A/119B may or may not extend into or through the barrier layer 108 in some examples. Because there is no intervening dielectric cap layer in the gate stack 113, the gate contact aperture 119C may be formed using a hybrid etch process including a single wet etch stage after a dry etch landing in the EC layer 112B. In this example, the single wet etch stage may be configured to remove the remaining EC layer 112B and extend the aperture 119C to land in or on the III-N cap layer 115 in a controllable manner (e.g., with or without material removal).

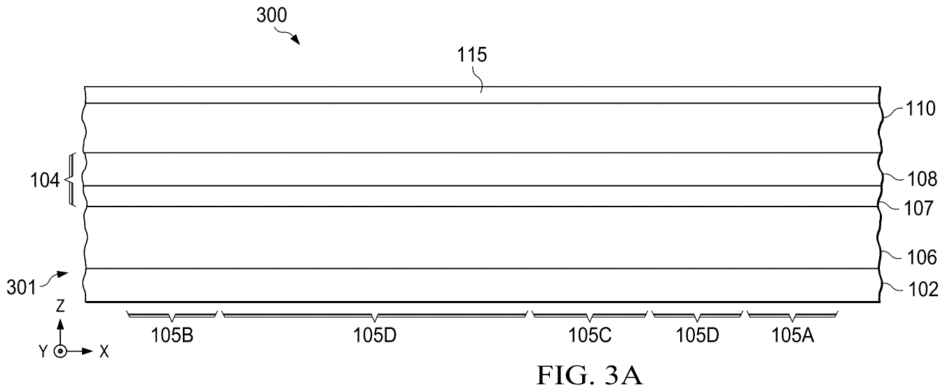

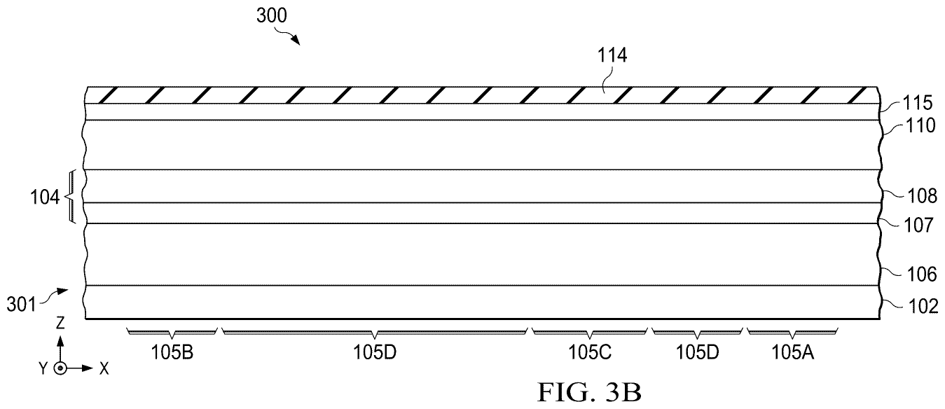

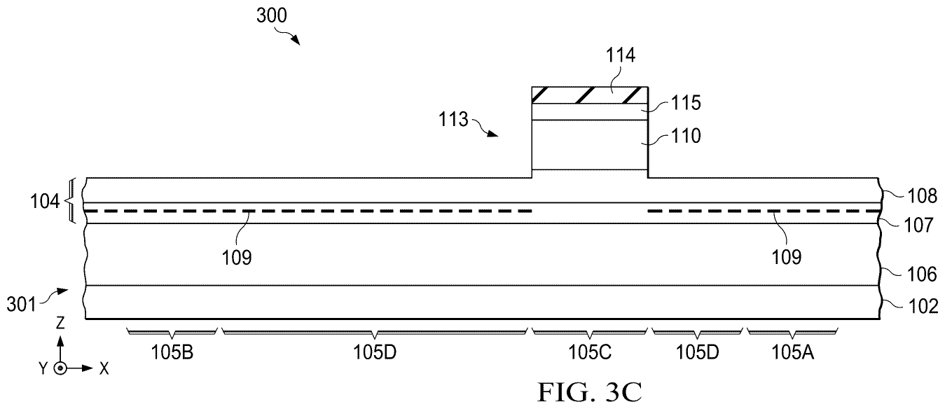

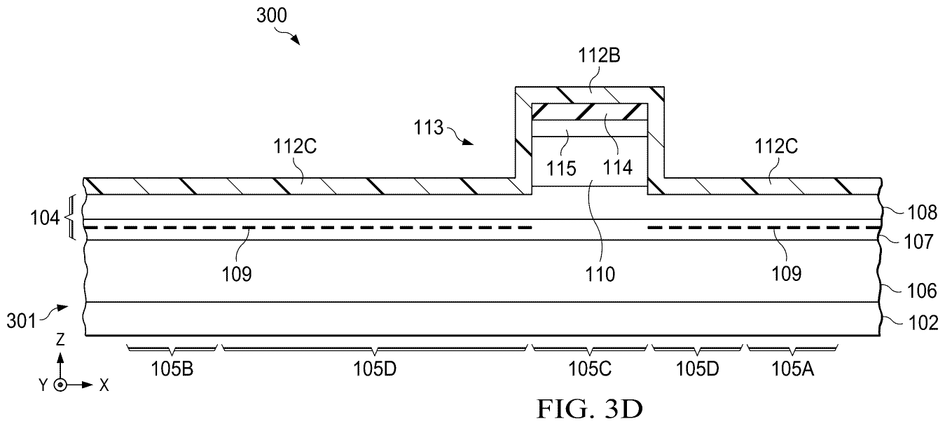

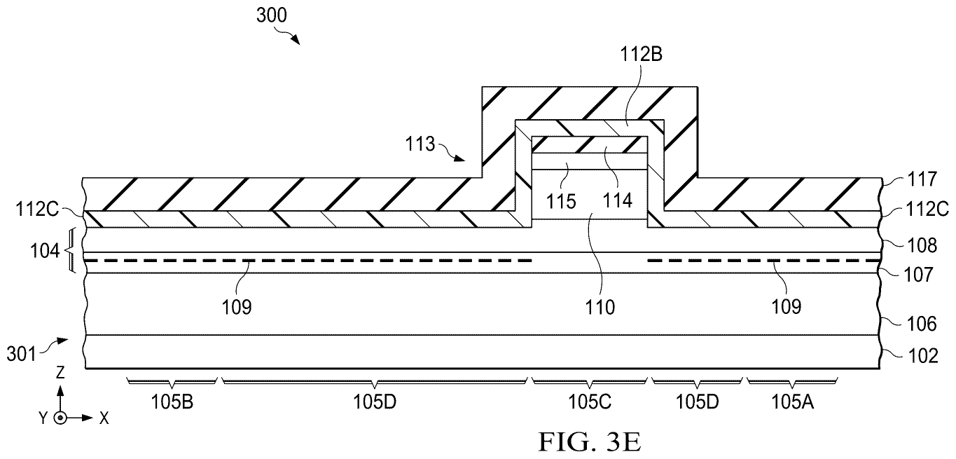

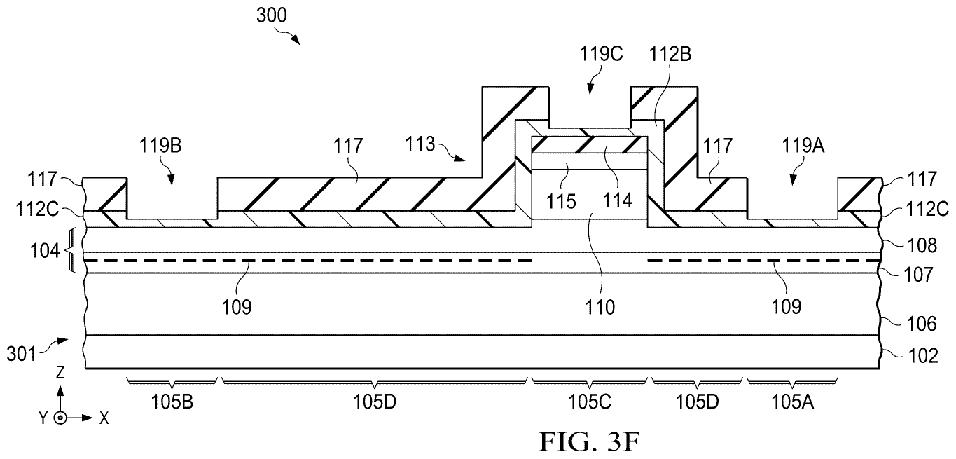

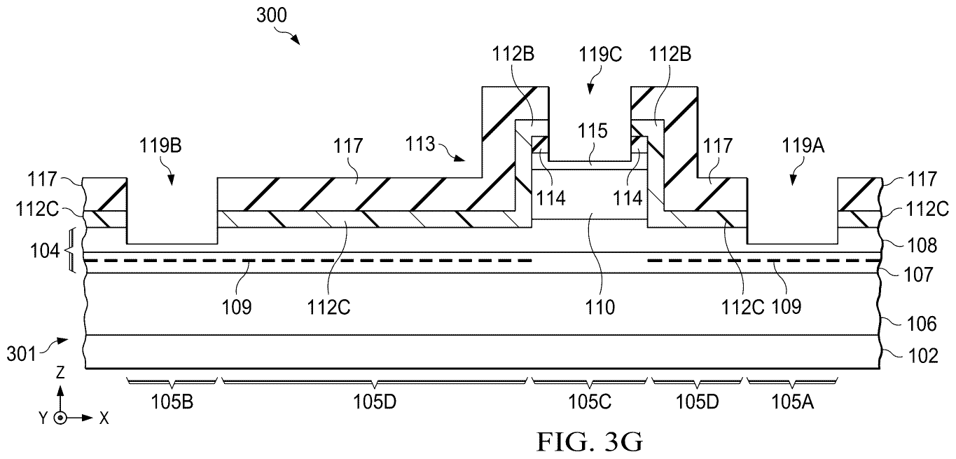

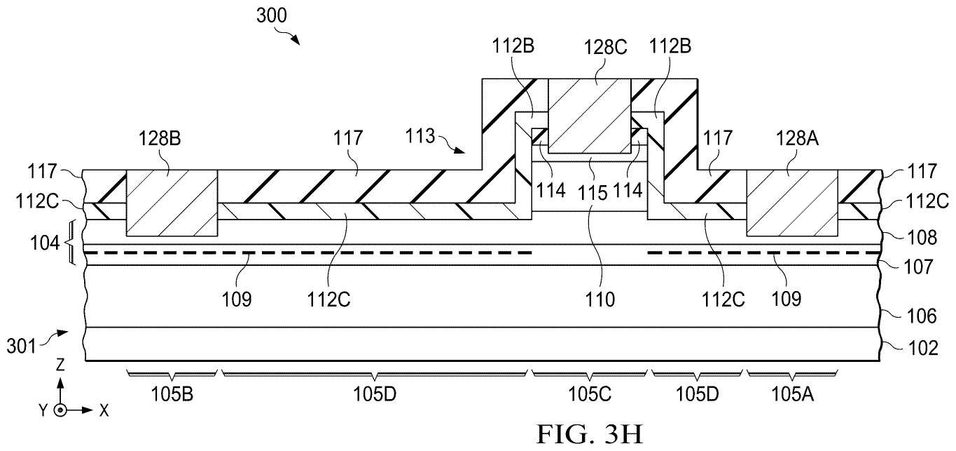

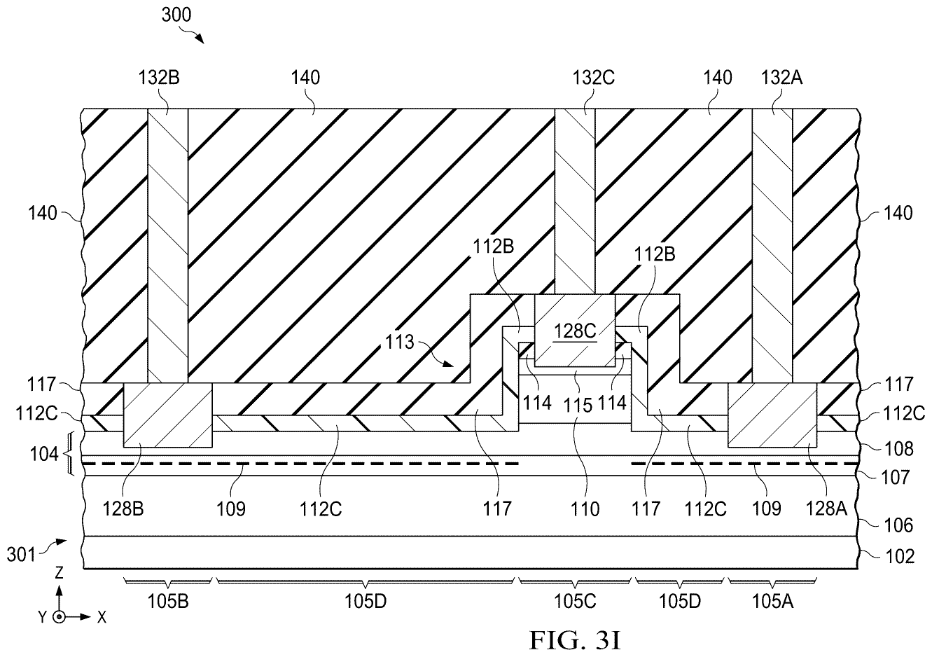

FIGS. 3A-3I depict cross-sectional views of a semiconductor device 300 at various stages of a process flow including hybrid etch control for gate stack formation according to one example. In this example, S/D contact apertures and gate contact aperture may be formed in a concurrent etch flow instead of having two separate mask/etch loops. FIGS. 3A-3I represent a process flow similar to the process flow depicted in FIGS. 1A-1K. Accordingly, the description set forth above with respect to the process flow of FIGS. 1A-1K is equally applicable to FIGS. 3A-3I with respect to corresponding parts and components unless otherwise noted. FIGS. 3A-3E show the formation of the semiconductor device 300 including a GaN device 301 at a passivation layer stage identical to the semiconductor device 100 shown in FIG. 1E. However, instead of forming S/D electrodes and gate electrode in two separate loops (e.g., in a gate first flow or a gate last flow), contact apertures for S/D and gate electrodes may be formed in a single etch loop using a concurrent hybrid etch flow in this example. Thereafter, S/D and gate electrodes may be formed using a single metallization process in an example. Accordingly, the mask count may be reduced by two (one contact etch mask and one metal etch mask) for fabricating the semiconductor device 300 in versions of this example.

FIG. 3F depicts a dry etch stage of a concurrent hybrid etch flow where the S/D contact apertures 119A/119B and gate contact aperture 119C are partially formed. A contact mask including patterning for S/D and gate contact apertures may be used in conjunction with a dry etch stage that removes material of the dielectric layer 117, stopping in the EC layer 112B in the gate region 105C and in the horizontal segment 112C of the EC layer 112B in the S/D regions 105A/105B.

FIG. 3G depicts a wet etch stage of a concurrent hybrid etch flow where remaining materials are removed in one or more etch steps. In one arrangement, a wet etch may be configured to remove the remaining portion of the EC layer 112B, the dielectric cap layer 114 (if included), and a portion of the III-N cap layer 115 in the gate stack 113 so as to land in the III-N cap layer 115 at a suitable depth. In this manner, a desirable thickness of the remaining III-N cap layer 115 may be obtained at the bottom of the gate contact aperture 119C. In some additional and/or alternative arrangements, a wet etch stage may be configured to land on the III-N cap layer 115 of the III-N gate stack 113 without removing/consuming the III-N cap material as previously noted.

In one arrangement, at least a portion of the wet etch may be configured to concurrently remove the remaining portion of the horizontal segment 112C of the EC layer 112B in the S/D regions 105A/105B so as to extend the S/D contact apertures 119A/B to a suitable depth as described previously. Depending on implementation, the contact apertures 119A/119B of the semiconductor device 300 may or may not extend into or through the barrier layer 108 in some examples as previously noted.

FIG. 3H depicts a stage where S/D electrodes 128A/128B and gate electrode 128C are formed in respective contact apertures 119A-119C using a suitable contact metallization and anneal process. In an example arrangement, an initial metal layer (e.g., a MET0, M0 or Metal 0 layer) of a multi-level metal interconnect scheme may be used for forming the S/D electrodes 128A/128B and gate electrode 128C as set forth previously. Because a single mask is used in the metallization process, the electrodes 128A-128C may include same metallic/conductive compositions according to an example herein. Similar to the examples above, a concurrent contact metallization process may include one or more metal layer depositions followed by patterning, etching, and cleaning and annealing.

In some arrangements, one or more additional dielectric layers, e.g., PECVD SiN layers, may be provided prior to forming a more completely formed semiconductor device 300. FIG. 3I depicts a more completely formed semiconductor device 300 including the GaN device 301 according to one example. Similar to the semiconductor device 100, suitable source and drain terminals 132A, 132B as well as a gate terminal 132C may be formed for making electrical contact with respective electrodes 128A-128C through an insulator stack 140.

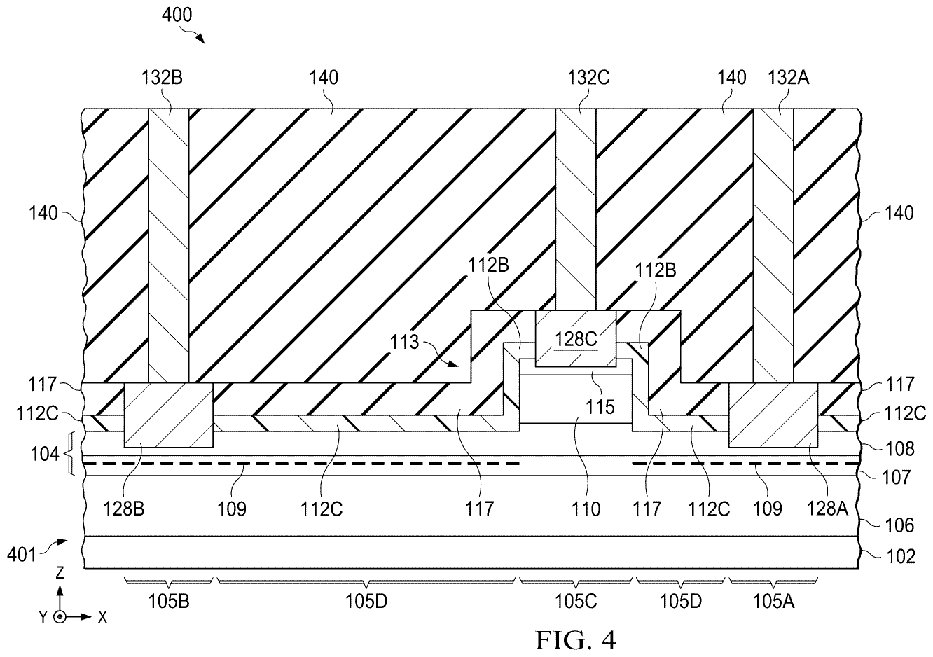

In one variation of the flow set forth in FIGS. 3A-3I, the dielectric cap layer 114 may be omitted in fabricating a semiconductor device using the concurrent hybrid etch flow. FIG. 4 depicts a semiconductor device 400 including a GaN device 401 fabricated using such a flow where the dielectric cap layer 114 is absent from the gate stack 113. The wet etch stage of the concurrent hybrid etch flow shown in FIG. 3G for forming completed contact apertures 119A-119C may be modified accordingly in order to account for the absence of the dielectric cap layer 114 in the gate stack 113. For example, because there is no intervening dielectric cap layer in the gate stack 113, the gate contact aperture 119C may be formed using a hybrid etch process including a single wet etch stage after a dry etch landing in the EC layer 112B. In this example, the single wet etch stage may be configured to remove the remaining EC layer 112B and extend the aperture 119C to land in or on the III-N cap layer 115 in a controllable manner, e.g., with or without material removal as noted previously. The contact apertures 119A/119B may be formed by removing the material from the dielectric layer 117, EC layer segment 112C as well as a portion of the heterojunction structure 104 in a similar manner as set forth above. As before, the contact apertures 119A/119B may or may not extend into or through the barrier layer 108 in some examples.

Although a concurrent hybrid etch flow may be used to form S/D and gate contact apertures in a single etch loop, two separate metal masks may be used for forming S/D and gate electrodes in some variations. Accordingly, the S/D and gate electrodes may have different metals in such variations.

With respect to the fabrication of devices using a concurrent hybrid etch flow according to the examples herein may therefore include aspects of the following steps in some implementations. Along with the formation of a gate contact aperture (e.g., the gate contact aperture 119C), source and drain contact apertures (e.g., apertures 119A/119B) may be formed in the source and drain regions 105A/105B, respectively, using the dry etch stage of the concurrent hybrid etch flow, where the dry etch stage of the concurrent flow stops in the EC layer segment 112C of the EC layer 112B overlying the barrier layer 108. As will be seen below, the EC layer 112B may be provided as a second EC layer in some variations, where the dry etch stage may stop on the segment 112C of such second EC layer overlying the barrier layer 108. The dry etch stage may be followed by the wet etch stage for removing a remaining portion of the segment 112C, where the wet etch stage may stop in or on the barrier layer (e.g., with or without removal of barrier layer material in some implementations). Thereafter, S/D electrodes, e.g., S/D electrodes 128A/128B, may be formed in the S/D contact apertures 119A/119B, respectively, along with the formation of gate electrode 128C, in some examples.

Where separate process loops are implemented in a flow with respect to the formation of S/D and gate electrodes, a first hybrid etch flow may be used for forming the S/D contact apertures and a second hybrid etch flow may be used for forming the gate contact aperture 119C, or vice versa. In versions of such examples, a wet etch stage may follow a dry etch stage for forming completed contact apertures with respect to a corresponding hybrid etch flow.

Further, where a III-N cap layer is provided as part of a gate stack, an example hybrid etch flow may include a wet etch stage that lands on the III-N cap layer with little or no material consumption in some variations as noted above.

In some examples, a III-N cap layer (e.g., an AlGaN cap layer) may be absent from the gate stack of a semiconductor device processed using separate etch loops for S/D and gate electrodes. Depending on whether a dielectric cap layer is present or not in the gate stack, further variations may be obtained in such a flow according to the teachings of the present disclosure.

In one variation of the flow shown in FIGS. 1A-1K, the step of forming a III-N cap layer over the p-GaN layer 110 may be omitted at the stage shown in FIG. 1A. Thereafter, the dielectric cap layer 114 is formed directly on the p-GaN layer 110 similar to the stage shown in FIG. 1B. In such a flow, the remaining fabrication stages may follow substantially in a similar manner. Accordingly, the S/D contact apertures 119A/119B may be formed by removing the material from the dielectric layer 117, EC layer segment 112C as well as a portion of the heterojunction structure 104 in the S/D regions 105A/105B as before. Because there is no III-N cap layer overlying the p-GaN layer 110 in the gate stack 113, the gate contact aperture 119C may be formed using a hybrid etch process that includes a suitable wet etch stage after a dry etch that lands in the EC layer 112B. In this example, the wet etch stage may be configured to remove the remaining EC layer 112B and the dielectric cap layer 114 to extend the aperture 119C to land in or on the p-GaN layer 110 in a controllable manner.

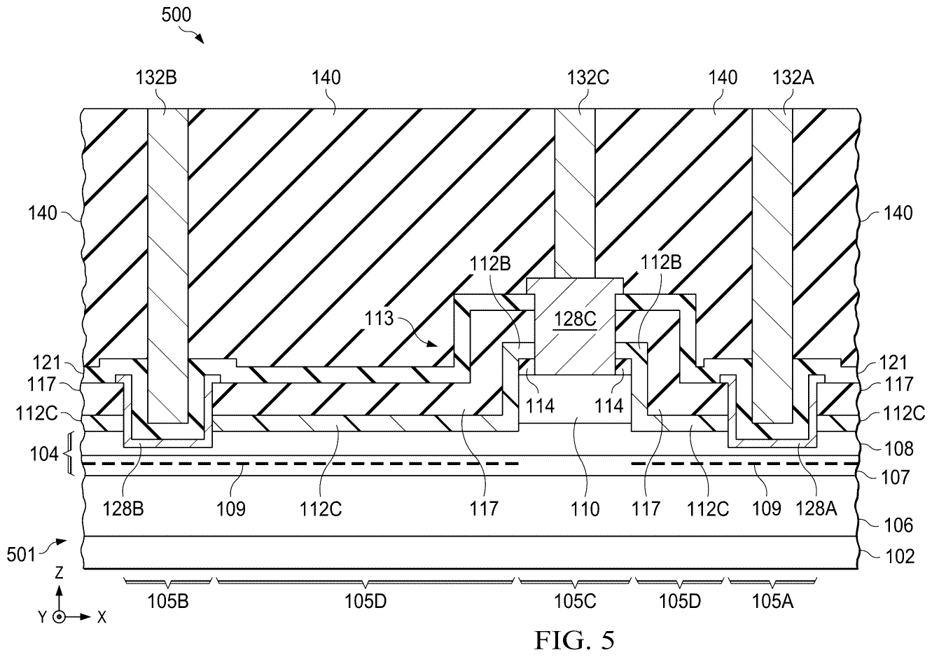

FIG. 5 depicts an example of a semiconductor device 500 including a GaN device 501 using the process flow variation set forth above with respect to the stages shown in FIGS. 1A-1K. Because the step of forming a III-N cap layer over the p-GaN layer 110 is omitted, the dielectric cap layer 114 is disposed directly on the p-GaN layer 110. As there is no intervening III-N cap layer, direct contact between the dielectric cap layer 114 and the p-GaN layer 110 is obtained. Furthermore, because the finishing wet etch stage extends the gate contact aperture 119C to land in or on the p-GaN layer 110, the gate electrode 128C is in direct contact with the p-GaN layer 110 in this example. In some versions of this example, there may be a portion of the dielectric cap layer 114 remaining over a portion of the p-GaN layer 110 not directly underneath the gate electrode 128C depending on the sizing of the landing of the gate contact aperture 119C. As illustrated in FIG. 5, the gate electrode 128C extends through the EC layer 112B and the dielectric cap layer 114, and contacts the p-GaN layer 110.

As the lack of a III-N cap layer in a gate stack may have no impact on the S/D contact aperture processing, S/D electrodes 128A/128B may be formed in the S/D regions 105A/105B, respectively, of the device 500 using a flow that includes some aspects of S/D electrode formation set forth above with respect to the formation of the device 100. In one example, S/D contact apertures 119A/119B may be formed by removing the material from the dielectric layer 117, EC layer segment 112C as well as a portion of the heterojunction structure 104 in the S/D regions 105A/105B as noted previously. Accordingly, the contact apertures 119A/119B, hence the S/D electrodes 128A/128B, may extend through the dielectric layer 117 and EC layer segment 112C, and may or may not extend into or through the barrier layer 108, e.g., into the channel layer 107, as described previously. Further, as the S/D and gate electrodes may be formed using two separate process loops, the S/D electrodes 128A/B and gate electrode 128C of the device 500 may have different metals in some examples.

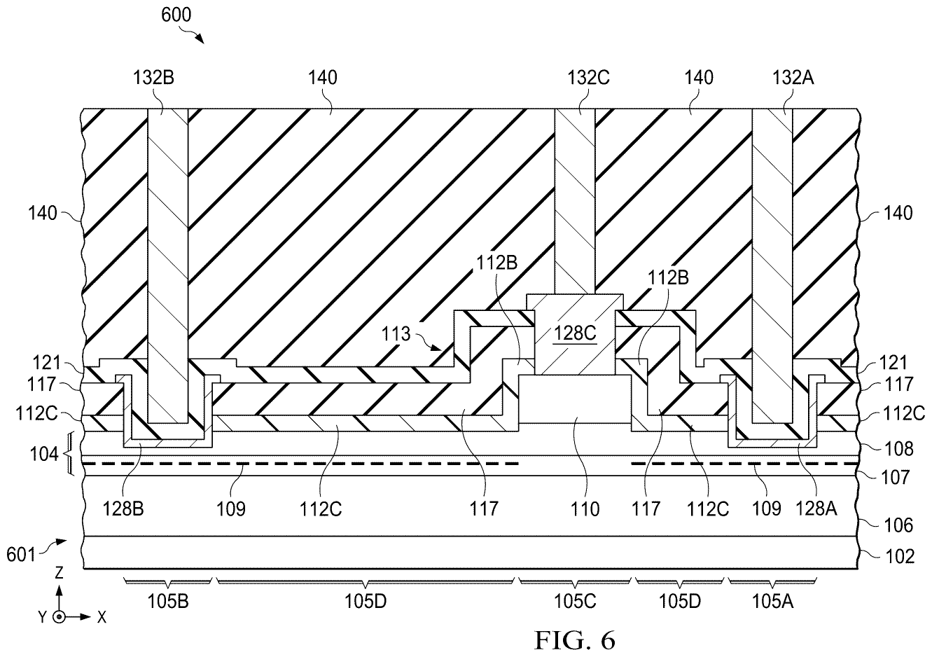

In another variation of the flow shown in FIGS. 1A-1K, both cap layers, e.g., III-N cap layer 115 and dielectric cap layer 114, may be omitted from the fabrication stages shown in FIGS. 1A and 1B. FIG. 6 depicts an example of a semiconductor device 600 including a GaN device 601 fabricated according to such a scenario. In this variation, the remaining fabrication stages for fabricating the device 600 may include aspects of the stages shown in FIGS. 1C-1K, which may follow substantially in a similar manner. Whereas the EC layer 112B is in direct contact with the p-GaN layer 110 in the gate region 105C, the horizontal segment 112C of the EC layer 112B remains in direct contact with the barrier layer 108 in the remaining device regions, e.g., the S/D regions 105A/105B and the access regions 105D as before.

In one arrangement, formation of S/D contact apertures 119A/119B in the S/D regions 105A/105B of the device 600 using a hybrid etch flow may include aspects of a dry etch stage followed by a wet etch stage as set forth previously. Because there are no cap layers disposed between the EC layer 112B and the p-GaN layer 110 in the gate stack 113, a wet etch stage for completing the gate contact aperture 119C may be modified accordingly. In this example, the wet etch stage may be configured to remove the remaining EC layer 112B (e.g., remaining after a dry etch landing therein) to extend the gate contact aperture 119C to land in or on the p-GaN layer 110 in a controllable manner.

As illustrated in FIG. 6, the semiconductor device 600 including the GaN device 601 depicts a gate electrode 128C that extends through the EC layer 112B and is disposed in direct contact with the p-GaN layer 110. The S/D electrodes 128A/128B, extending through the EC layer segment 112C, may or may not extend into or through the barrier layer 108 (e.g., into the channel layer 107) in some examples as described previously. Similar to the device 500 shown in FIG. 5, the S/D electrodes 128A/B and gate electrode 128C of the device 600 may have different metals in some examples because of the separate S/D and gate electrode etch/metal loops used for fabricating the device 600.

In some arrangements, a III-N cap layer may be absent from the gate stack of a semiconductor device processed using a concurrent hybrid etch flow in the formation of S/D and gate electrodes. Moreover, further variations may be obtained in such a process flow depending on whether a dielectric cap layer is present or not in the gate stack, similar to the foregoing examples.

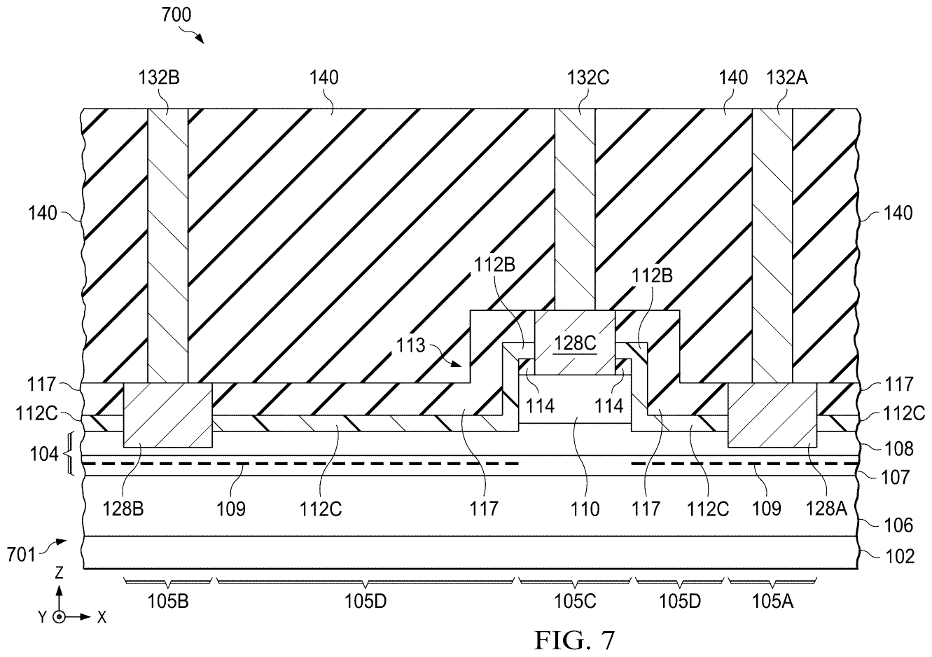

For example, in one variation of the flow shown in FIGS. 3A-3I, a III-N cap layer may be omitted while a dielectric cap layer is preserved. FIG. 7 depicts a semiconductor device 700 including a GaN device 701 fabricated using such a flow where the formation of a III-N cap layer may be omitted from the stage shown in FIG. 3A. Remaining stages of the process flow including formation of the dielectric cap layer 114 over the p-GaN layer may follow as before. Accordingly, a concurrent dry etch stage for partially forming the S/D and gate contact apertures 119A-119C may remain substantially the same as before, e.g., as depicted in FIG. 3F. On the other hand, a wet etch stage of the concurrent hybrid etch flow shown in FIG. 3G for forming completed contact apertures 119A-119C may be modified in order to account for the absence of a III-N cap layer in the gate stack 113. In this example, a concurrent wet etch stage may be configured to remove the remaining EC layer 112B and the dielectric cap layer 114 to extend the aperture 119C to land in or on the p-GaN layer 110 in a controllable manner. Accordingly, the gate electrode 128C is disposed in direct contact with the p-GaN layer 110 in this example as shown in FIG. 7. In some versions of this example, there may be a portion of the dielectric cap layer 114 remaining over a portion of the p-GaN layer not directly underneath the gate electrode 128C depending on the sizing of the landing of the gate contact aperture 119C.

As illustrated in FIG. 7, the gate electrode 128C extends through the EC layer 112B and the dielectric cap layer 114, and contacts the p-GaN layer 110. The S/D electrodes 128A/128B, extending through the EC layer segment 112C, may or may not extend into or through the barrier layer 108 (e.g., into the channel layer 107) in some examples as described previously. Further, as the S/D electrodes 128A/128B and gate electrode 128C may be formed using concurrent process loops, the S/D electrodes 128A/128B and gate electrode 128C may have a same metal in some example implementations.

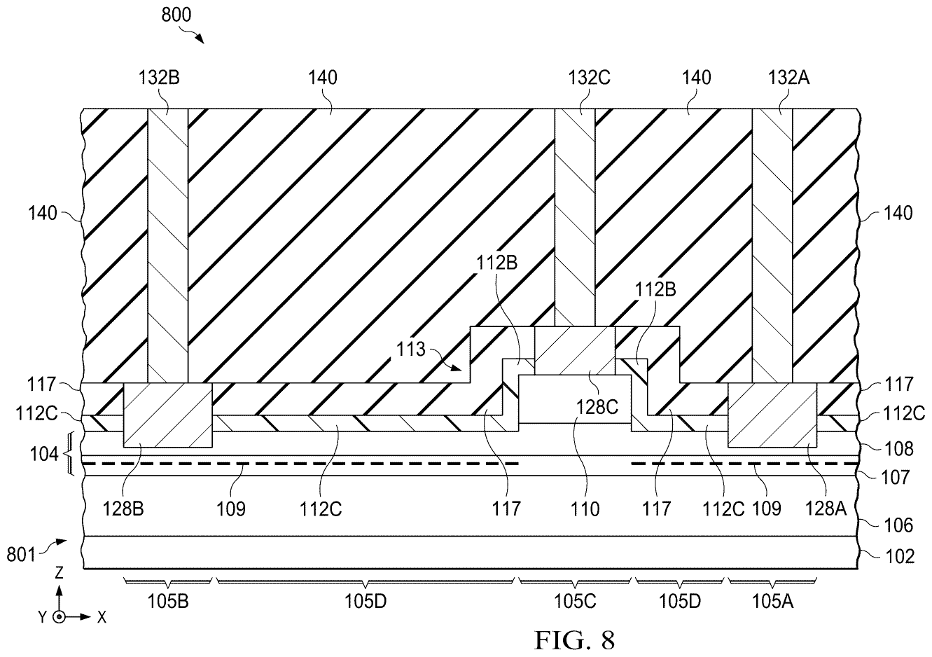

In another variation of the flow shown in FIGS. 3A-3I, both cap layers, e.g., III-N cap layer 115 and dielectric cap layer 114, may be omitted similar to some examples set forth above. FIG. 8 depicts a semiconductor device 800 including a GaN device 801 fabricated using such a flow where the formation of cap layers is omitted from the stages of FIGS. 3A and 3B, with subsequent stages following in a similar manner. Accordingly, a concurrent dry etch stage for partially forming the S/D and gate contact apertures 119A-119C may remain the same as before, e.g., as depicted in FIG. 3F. However, a concurrent wet etch stage shown in FIG. 3G may be modified for forming completed contact apertures 119A-119C in order to account for the absence of III-N cap and dielectric cap layers in the gate stack 113. In this example, a concurrent wet etch stage may be configured to remove the remaining EC layer 112B and extend the aperture 119C to land in or on the p-GaN layer 110 in a controllable manner. Accordingly, the gate electrode 128C is disposed in direct contact with the p-GaN layer 110 in this example as shown in FIG. 8.

As illustrated, the gate electrode 128C extends through the EC layer 112B and contacts the p-GaN layer 110. The S/D electrodes 128A/128B, extending through the EC layer segment 112C, may or may not extend into or through the barrier layer 108 (e.g., into the channel layer 107) in some examples as described previously. Further, as the S/D electrodes 128A/128B and gate electrode 128C may be formed using concurrent process loops, the S/D electrodes 128A/128B and gate electrode 128C of the device 800 may have a same metal in some example implementations.

In some further examples, a dielectric cap layer may be replaced with an EC layer before patterning the p-GaN stack of a semiconductor device. Additional variations may be obtained in such a process flow depending on whether a III-N cap layer is present or not in the gate stack and/or whether a concurrent hybrid etch process is used, similar to the foregoing examples.

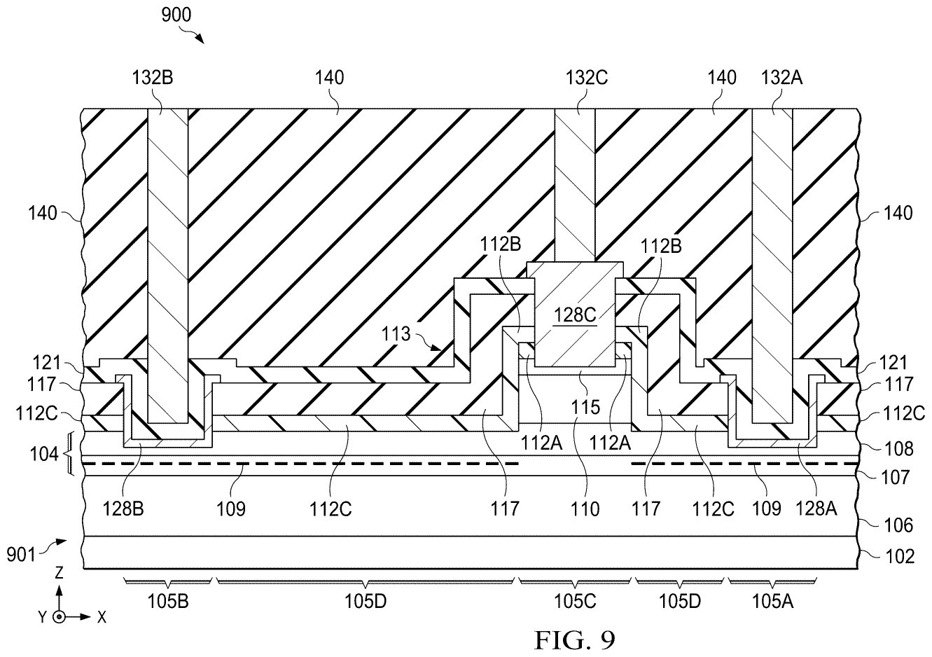

In one variation of the flow shown in FIGS. 1A-1K, the step of forming a dielectric cap layer over the III-N cap layer 115 may be replaced with an ALD process at the stage shown in FIG. 1B. FIG. 9 depicts an example of a semiconductor device 900 including a GaN device 901 where the dielectric cap layer 114 overlying the III-N cap layer 115 in the gate stack 113 is replaced with a suitable EC layer formed by ALD. In versions of this example where an EC layer is deposited over the III-N cap layer 115 before a p-GaN gate stack is formed, such an EC layer may be referred to as a first etch control layer 112A. In some versions, the first etch control layer 112A may also be referred to as a first ALD layer or an ALD cap layer.

In one arrangement, the first EC layer 112A may comprise similar materials such as the EC layer 112B described above, e.g., Al₂O₃, AlN, and/or a combination thereof, and the like. Because the EC layer 112B is deposited after the p-GaN gate stack 113 is formed, the EC layer 112B may be referred to as a second etch control layer or second ALD layer in some versions. In one arrangement, the first EC layer 112A may have a thickness of about 50 nm to 200 nm. As the first EC layer 112A does not extend beyond the gate region 105C, S/D contact apertures 119A/119B may be formed using a hybrid etch process substantially similar to the process set forth above with respect to the stage shown in FIG. 1F. As the gate stack 113 contains similar ALD material over the III-N cap layer 115, the gate contact aperture 119C may be formed using a hybrid etch process including a single wet etch stage after a dry etch landing in the EC layer 112B. In this example, the single wet etch stage may be configured to remove the remaining EC layer 112B as well as the first EC layer 112A and extend the aperture 119C to land in or on the III-N cap layer 115 in a controllable manner, with or without material removal as previously noted.

As illustrated in FIG. 9, the semiconductor device 900 including the GaN device 601 depicts a gate electrode 128C that extends through the second EC layer 112B and the first EC layer 112A, and is disposed in direct contact with the III-N cap layer 115. The S/D electrodes 128A/128B, extending through the EC layer segment 112C, may or may not extend into or through the barrier layer 108 (e.g., into the channel layer 107) in some examples as described previously. Further, as the S/D and gate electrodes may be formed using two separate process loops, the S/D electrodes 128A/B and gate electrode 128C of the device 900 may have different metals in some examples.

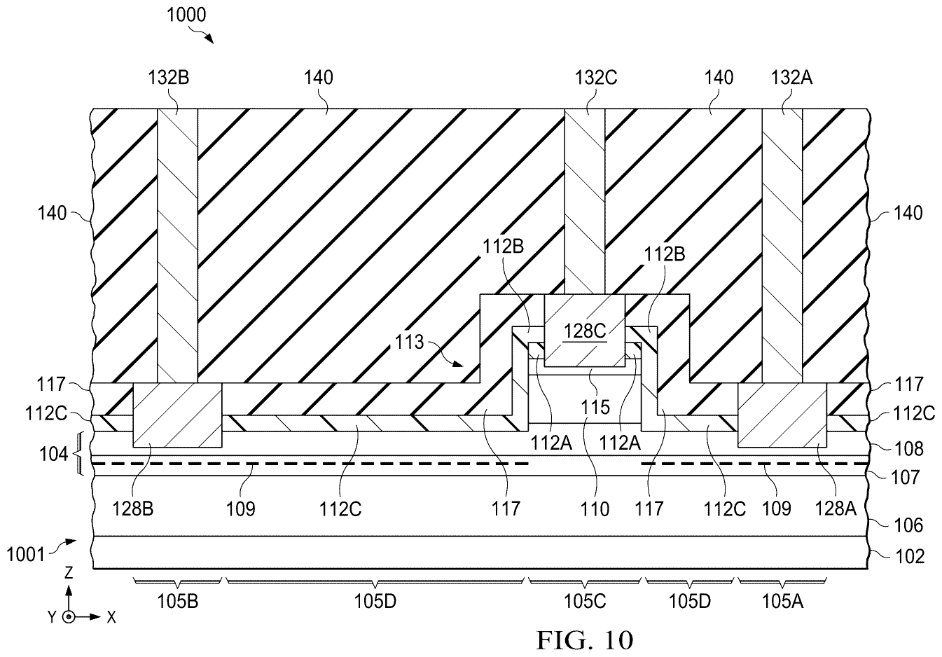

In similar fashion, a dielectric cap layer may be replaced in some examples with an EC layer in a process flow including a concurrent hybrid etch scheme, e.g., as shown in FIGS. 3A-3I. Accordingly, the step of forming a dielectric cap layer over the III-N cap layer 115 may be replaced with an ALD process at the stage shown in FIG. 3B to form a first EC layer 112A as set forth above. FIG. 10 depicts an example of a semiconductor device 1000 including a GaN device 1001 where the gate stack 113 includes the first EC layer 112A overlying the III-N cap layer 115. As noted above, the first EC layer 112A is confined to the gate region 105C. Accordingly, a concurrent dry etch stage for partially forming the S/D and gate contact apertures 119A-119C may remain the same as before, e.g., as depicted in FIG. 3F. On the other hand, a concurrent wet etch stage shown in FIG. 3G may be suitably modified for forming completed contact apertures 119A-119C due to the replacement of LPCVD dielectric cap material (e.g., SiN) with ALD material (e.g., Al₂O₃/AlN) in the gate stack 113. In this example, a concurrent wet etch stage may be configured to remove the remaining EC layer 112B as well as the first EC layer 112A and extend the aperture 119C to land in or on the III-N cap layer 115 in a controllable manner (e.g., with or without material removal).

As illustrated in FIG. 10, the gate electrode 128C extends through the EC layers 112B, 112A and contacts the III-N cap layer 115. The S/D electrodes 128A/128B, extending through the EC layer segment 112C, may or may not extend into or through the barrier layer 108 (e.g., into the channel layer 107) in some examples as described previously. Further, as the S/D electrodes 128A/128B and gate electrode 128C may be formed using concurrent process loops, the S/D electrodes 128A/128B and gate electrode 128C of the device 1000 may have a same metal in some example implementations.

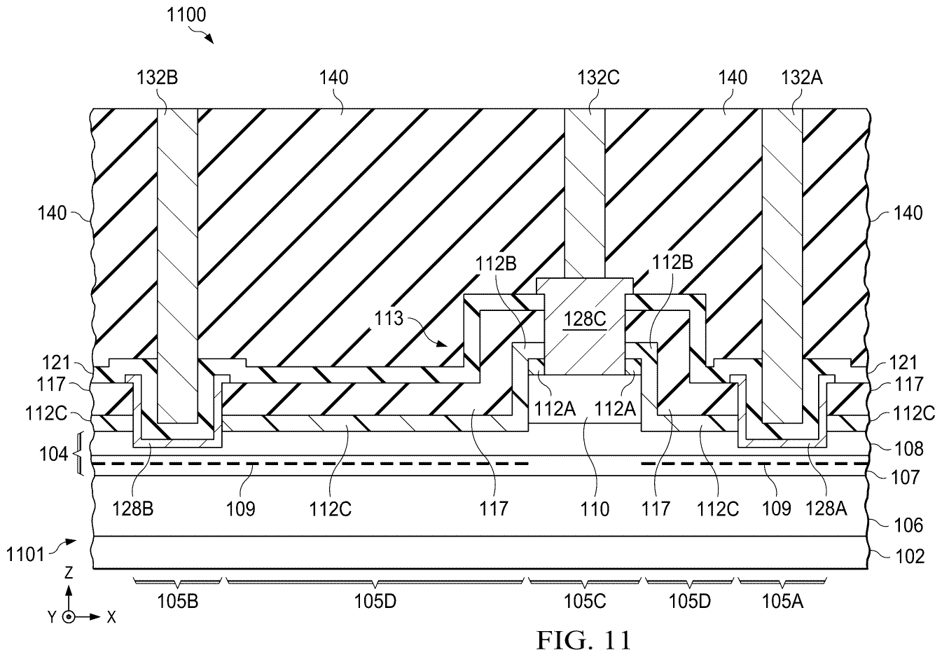

In some arrangements, replacement of a dielectric cap layer with an EC layer may be coupled with omitting a III-N cap layer of a semiconductor device. In one variation of the flow shown in FIGS. 1A-1K, the formation of a III-N cap layer 115 is omitted in the stage of FIG. 1A followed by the formation of a first EC layer 112A instead of a dielectric cap layer 114 in the stage of FIG. 1B. FIG. 11 depicts an example of a semiconductor device 1100 including a GaN device 1101 where the first EC layer 112A is directly disposed on the p-GaN layer 110. Similar to the examples above, the formation of S/D contact apertures 119A/119B may remain substantially the same, whereas a wet etch stage for completing the gate contact aperture 119C may be suitably modified to remove the remaining EC layer 112B as well as the first EC layer 112A and extend the aperture 119C to land directly in or on the p-GaN layer 110.

As illustrated in FIG. 11, the gate electrode 128C extends through the EC layers 112B, 112A and contacts the p-GaN layer 110. The S/D electrodes 128A/128B, extending through the EC layer segment 112C, may or may not extend into or through the barrier layer 108 (e.g., into the channel layer 107) in some examples. Further, as the S/D electrodes 128A/128B and gate electrode 128C may be formed using separate etch/metal process loops, the S/D electrodes 128A/128B and gate electrode 128C of the device 1100 may have different metals in some example implementations.

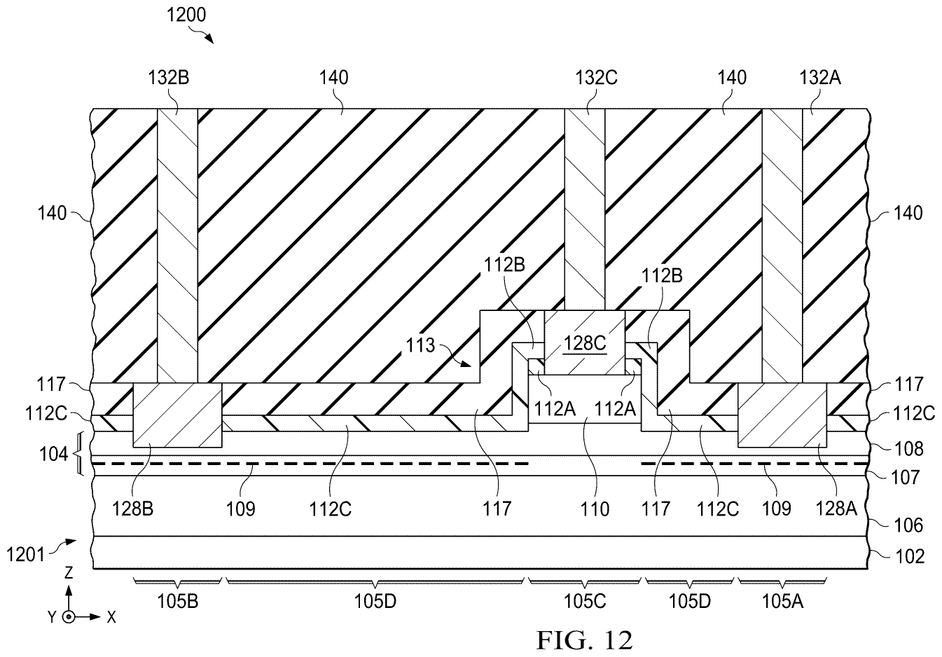

In similar fashion, a process flow including a concurrent hybrid etch scheme, e.g., as shown in FIGS. 3A-3I, may be modified to replace a dielectric cap layer with an EC layer while omitting a III-N cap layer in a semiconductor device. FIG. 12 depicts an example of a semiconductor device 1200 including a GaN device 1201 where the gate stack 113 includes the first EC layer 112A is directly disposed on the p-GaN layer 110. As before, a concurrent wet etch stage for completing the gate contact aperture 119C may be suitably modified to remove the remaining EC layer 112B as well as the first EC layer 112A and extend the aperture 119C to land directly in or on the p-GaN layer 110.

As illustrated in FIG. 12, the gate electrode 128C extends through the EC layers 112B, 112A and contacts the p-GaN layer 110. The S/D electrodes 128A/128B, extend through the EC layer segment 112C and may or may not extend into or through the barrier layer 108 (e.g., into the channel layer 107) in some examples as described previously. Further, as the S/D electrodes 128A/128B and gate electrode 128C may be formed using concurrent process loops, the S/D electrodes 128A/128B and gate electrode 128C of the device 1200 may have a same metal in some example implementations.

Some additional and/or alternative examples of the present disclosure may integrate a hybrid etch scheme in association with multiple etch control layers as well as a dielectric cap layer in a GaN process flow. Depending on whether a III-N cap layer is present or not in the gate stack, further variations may be obtained in such a flow according to the teachings of the present disclosure.

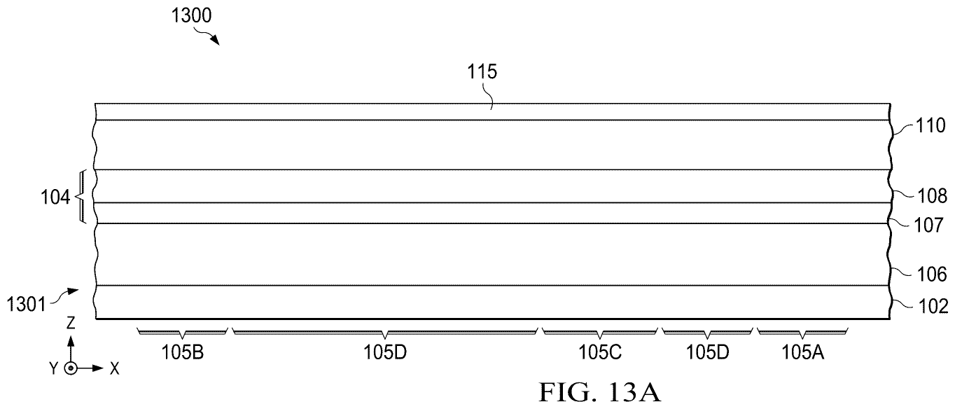

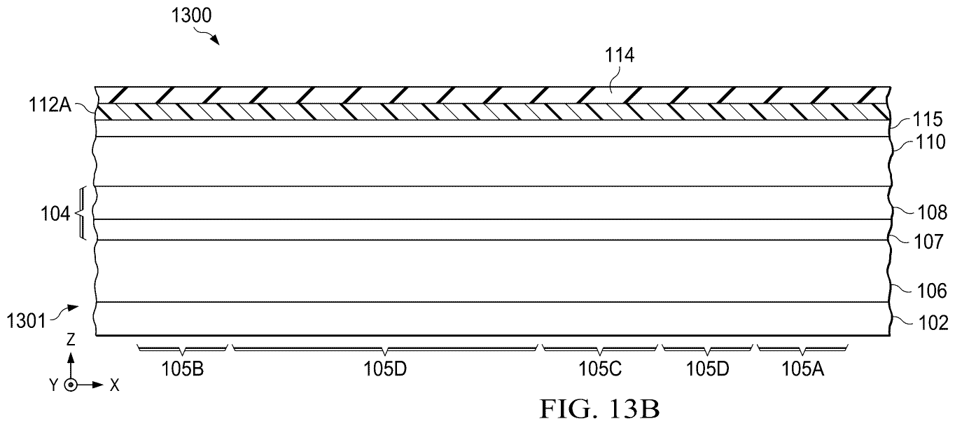

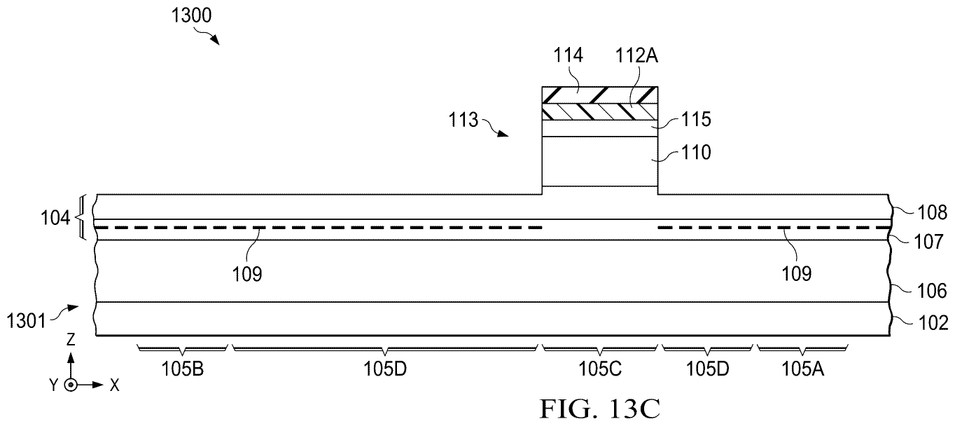

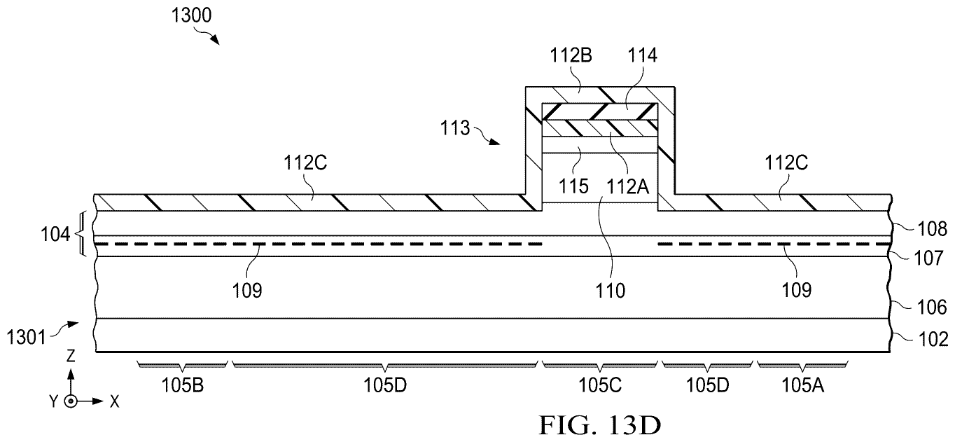

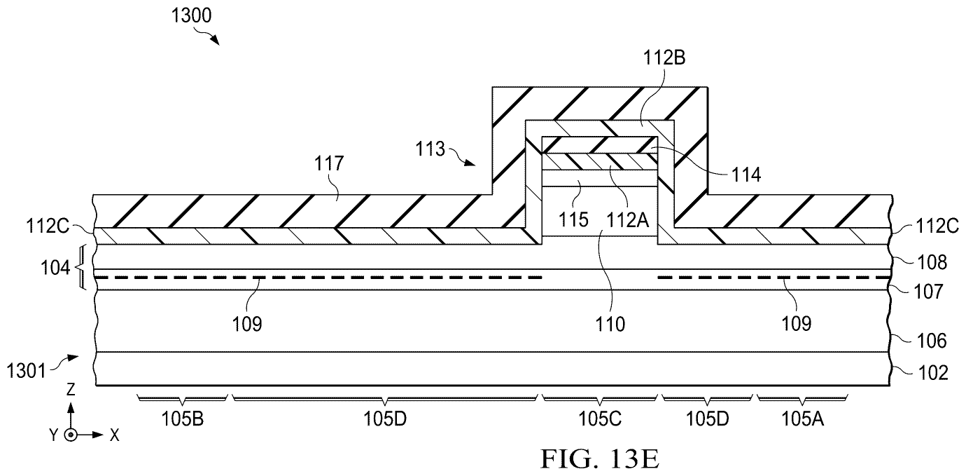

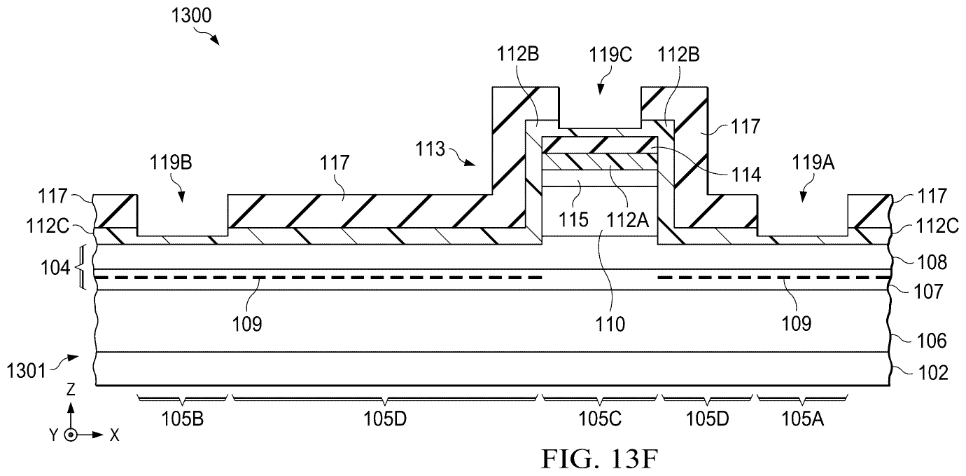

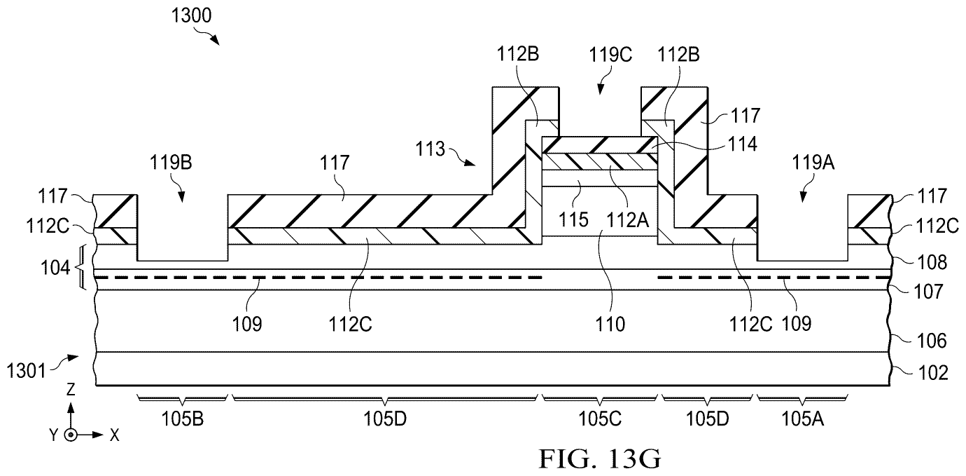

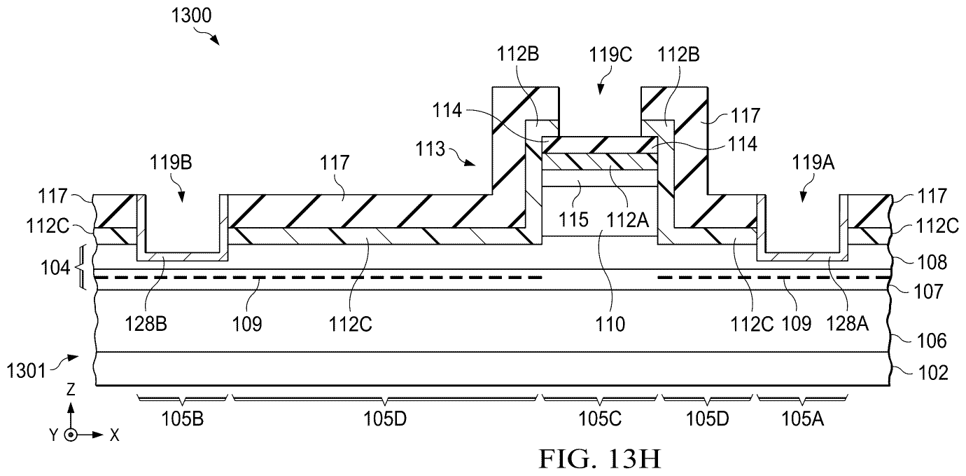

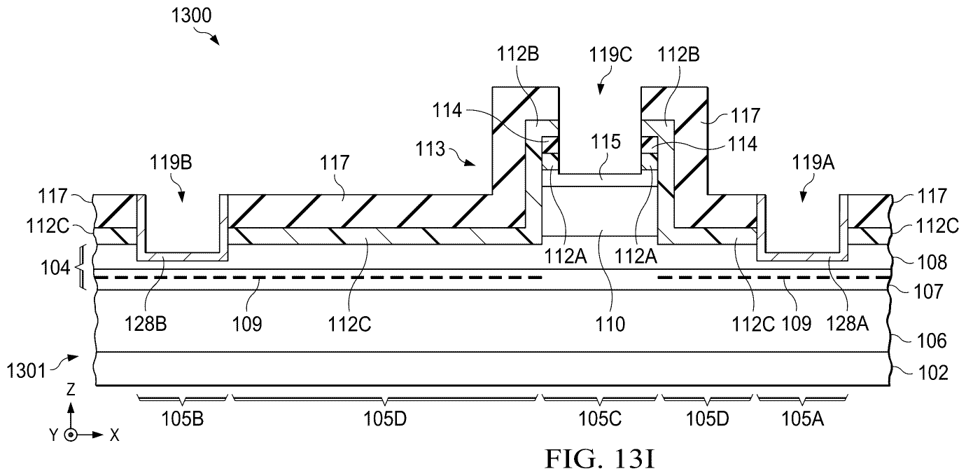

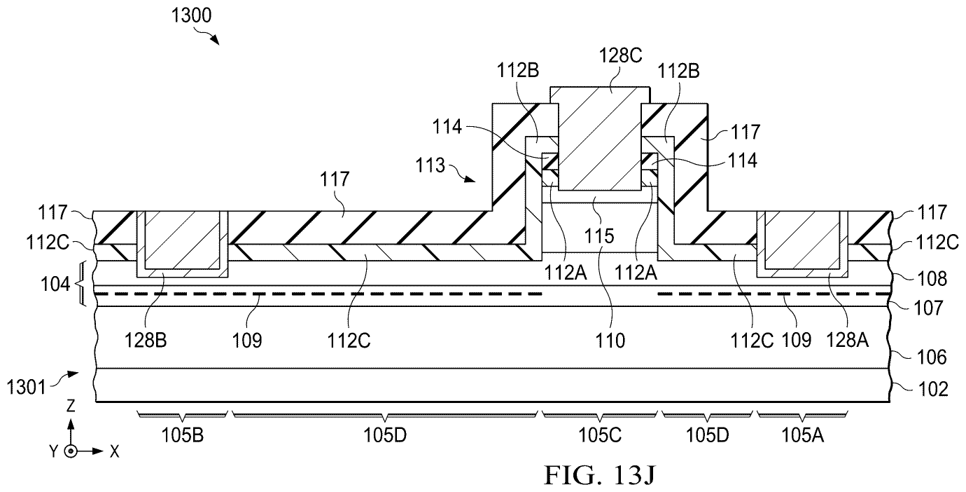

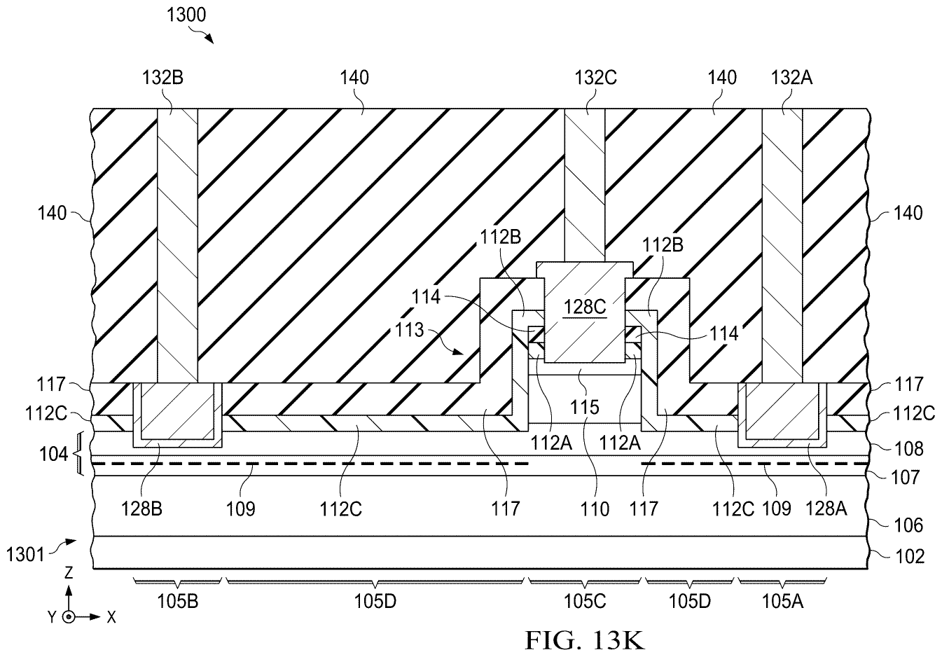

FIGS. 13A-13K depict cross-sectional views of a semiconductor device 1300 at various stages of a process flow including hybrid etch control for gate stack formation according to an example of the present disclosure. In this example, S/D contact apertures and gate contact aperture may be formed in a concurrent etch flow including multiple etch control layers (e.g., ALD layers). As illustrated, FIGS. 13A-13K include aspects of the process flow depicted in FIGS. 3A-3I. Accordingly, the description set forth above with respect to certain aspects of the process flow of FIGS. 3A-3I is equally applicable to FIGS. 13A-13K with respect to corresponding parts and components unless otherwise noted herein. As will be seen below, by using two EC layers sandwiching an LPCVD dielectric cap layer in a gate stack, one mask level may be eliminated by combining S/D and gate contact etches as previously, while still allowing the use of separate metals for S/D and gate electrodes. Accordingly, the mask count may be reduced by one in this example (e.g., in comparison to the S/D and gate contact formation scheme described with reference to FIGS. 1A-1K) for fabricating the semiconductor device 1300 with separate S/D and gate metallization processes. This reduction in mask count is different from the process flow of FIGS. 3A-3I that reduces the mask count by two (e.g., in comparison to the S/D and gate contact formation scheme described with reference to FIGS. 1A-1K) with single metallization for S/D and gate electrodes in some examples as described above.

FIGS. 13A-13E show the formation of the semiconductor device 1300 including a GaN device 1301 at a passivation layer stage similar to the stages set forth in FIGS. 3A-3E except that a first EC layer 112A, e.g., a first ALD layer, is deposited over the III-N cap layer 115 (e.g., comprising an AlGaN layer) before an etch process (e.g., p-GaN etch) is performed for patterning a p-GaN gate as part of a gate stack 113, as illustrated in the stage of FIG. 1C. After performing a gate stack etch to form the gate stack 113, a second EC layer, e.g., operable as the EC layer 112B in the examples above, is deposited. Accordingly, in versions of this example, the gate stack 113 comprises an EC/cap/EC sandwich over the III-N cap layer 115. Thereafter, a suitable dielectric layer, e.g., dielectric layer 117, is formed over the semiconductor device 1300 as shown in FIG. 13E.

FIG. 13F depicts a dry etch stage of a concurrent hybrid etch flow where the S/D contact apertures 119A/119B and gate contact aperture 119C are partially formed. A contact mask including patterning for S/D and gate contact apertures may be used in conjunction with a dry etch stage that removes material of the dielectric layer 117, stopping in the EC layer 112B in the gate region 105C and in the horizontal segment 112C of the EC layer 112B in the S/D regions 105A/105B.

FIG. 13G depicts a wet etch stage of a concurrent hybrid etch flow where remaining materials are removed in one or more etch steps. In one arrangement, a wet etch (e.g., a first wet etch step) may be configured to remove the remaining portion of the horizontal segment 112C of the EC layer 112B in the S/D regions so as to land in the barrier layer 108 at a suitable depth. In some arrangements, the wet etch may stop on a top surface of the barrier layer 108, e.g., without removing material, as previously noted. Further, the first wet etch step may be configured to remove the remaining portion of the EC layer 112B in the gate stack 113 so as to land in or on the dielectric cap layer 114.

FIG. 13H depicts a stage where S/D electrodes 128A, 128B may be formed using a suitable metal layer (e.g., MET0 layer) in a deposition/pattern/etch process as described previously. Further, a post-metal clean and anneal process may be performed at this stage.

FIG. 13I depicts another wet etch step (e.g., a second wet etch step) operable to remove remaining material over the III-N cap layer 115 in a sequence of etch operations after the formation of the S/D electrodes 128A/128B. In an example arrangement, a BHF etch may be performed to remove the dielectric cap layer 114 and an SC1 etch may be performed to remove the first EC layer 112A such that the gate contact aperture 119C is extended to a suitable depth into the III-N cap layer 115 of the gate stack 113. In some arrangements, a wet etch step may be configured to terminate on a top surface of the III-N cap layer 115 (e.g., without removal of material) as noted previously. Thereafter, a p-GaN activation anneal step may be performed to activate the dopant species.

FIG. 13J depicts a stage where the gate electrode 128C may be formed using a metal different from the metal(s) used for forming the S/D electrodes 128A, 128B. In one example, the gate metal may form a stack over the S/D electrodes 128A, 128B as shown in FIG. 13J although this is not a requirement. In some arrangements, for example, the gate metal over the S/D electrodes 128A/128B may be removed using a metal etch process including over etch. As illustrated, the gate electrode 128C extends through the EC layer 112B, the dielectric cap layer 114 and the EC layer 112A, and contacts the III-N cap layer 115.

FIG. 13K depicts a more completely formed semiconductor device 1300 including the GaN device 1301 having different metals for the S/D and gate electrodes 128A-128C. Similar to the semiconductor device 300, suitable source and drain terminals 132A, 132B as well as a gate terminal 132C may be formed for making electrical contact with respective electrodes 128A-128C through an insulator stack 140.

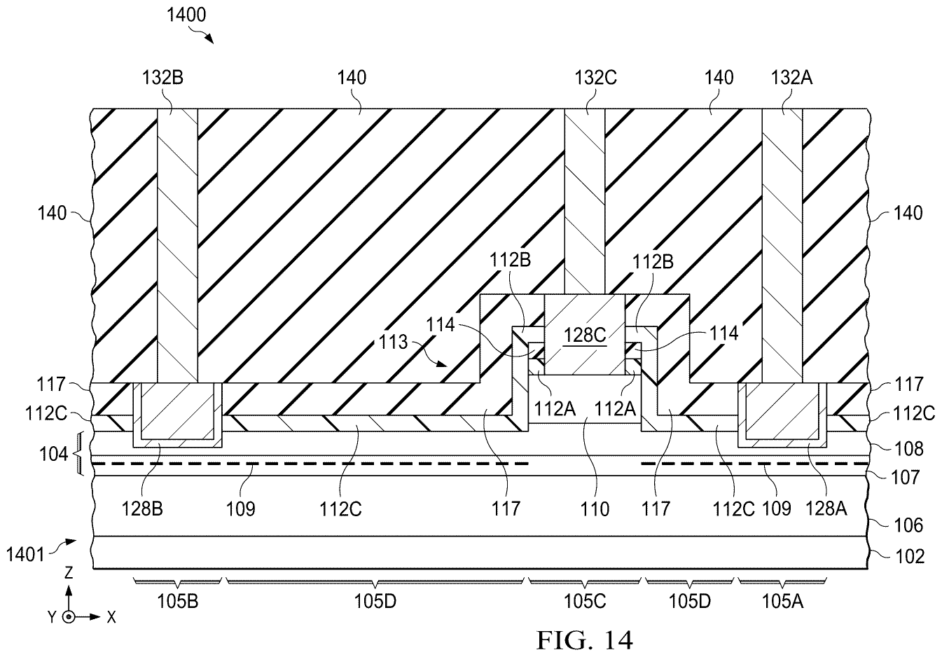

In one variation of the flow set forth in FIG. 13A-13K, the III-N cap layer 115 may be omitted in fabricating a semiconductor device using the concurrent hybrid etch flow. FIG. 14 depicts a semiconductor device 1400 including a GaN device 1401 fabricated using such a flow where the III-N cap layer 115 is absent from the gate stack 113. As the wet etch stage of the concurrent hybrid etch flow shown in FIG. 13I may be configured to land on the p-GaN layer 110, the gate electrode 128C is therefore in direct contact with the p-GaN layer 110 in this example.

As illustrated in FIG. 14, the gate electrode 128C extends through the EC layer 112B, the dielectric cap layer 114 and the EC layer 112A, and contacts the p-GaN layer 110. Further, as the S/D electrodes 128A/128B and gate electrode 128C may be formed using different masks after a concurrent etch process, the S/D electrodes 128A/128B and gate electrode 128C of the device 800 may have different metals in some example implementations as set forth above.

In some arrangements, an ALD layer operable as an EC layer may be formed before forming a gate stack, e.g., before performing a p-GaN etch. Similar to the variations set forth above, further variations may be obtained in such a flow depending on whether a dielectric cap layer or a III-N cap layer is present or not in the gate stack of a semiconductor device.

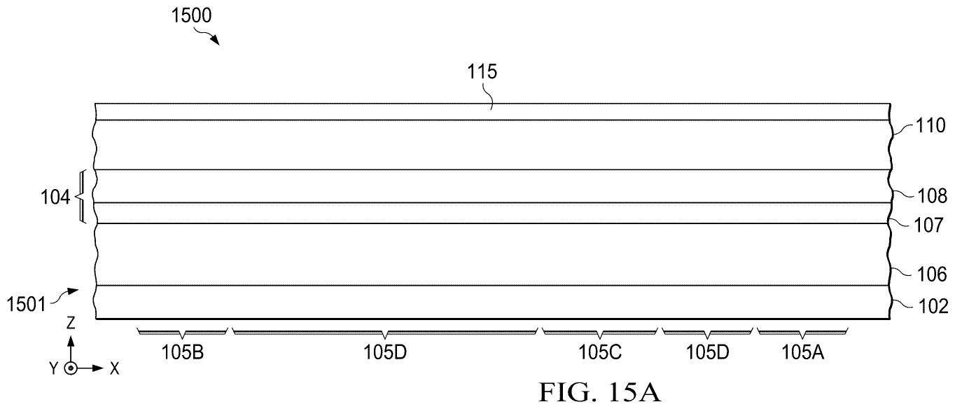

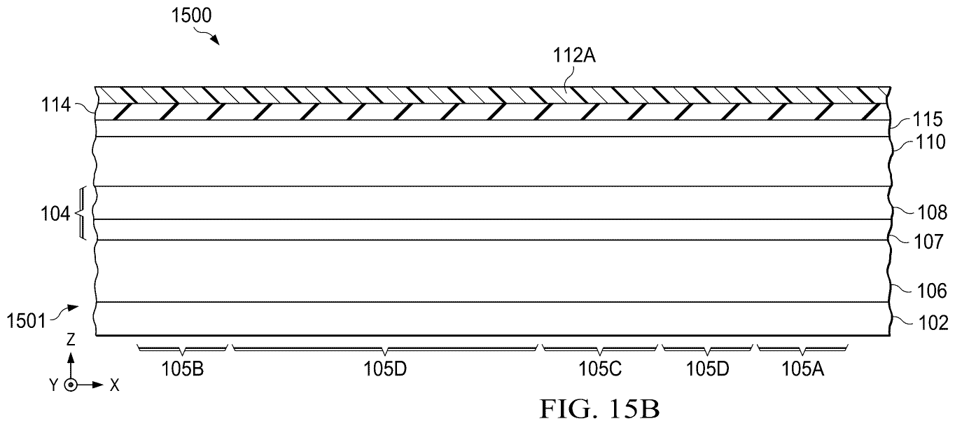

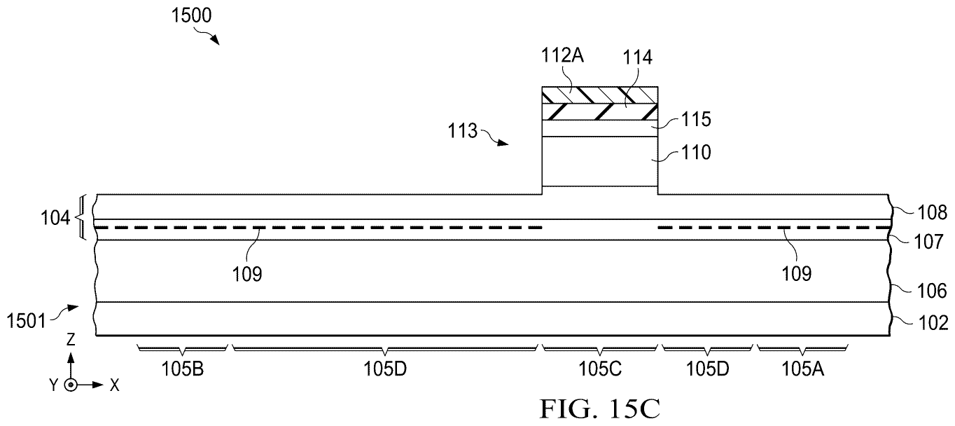

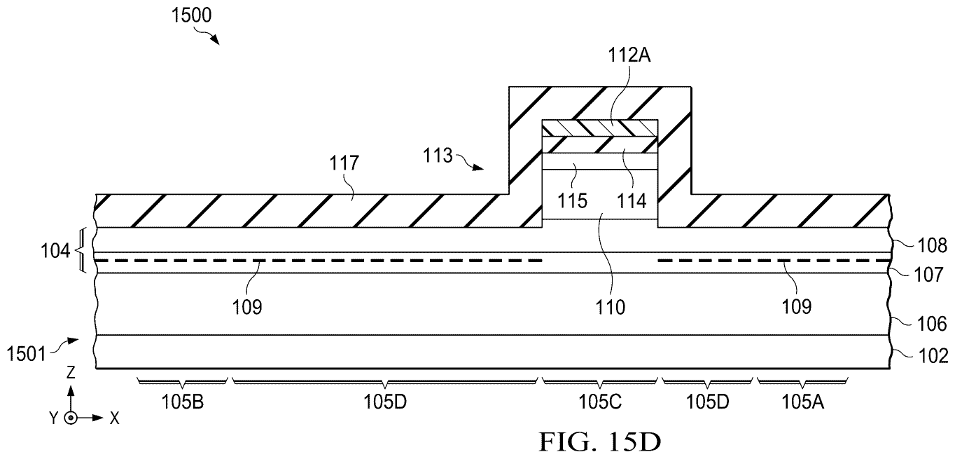

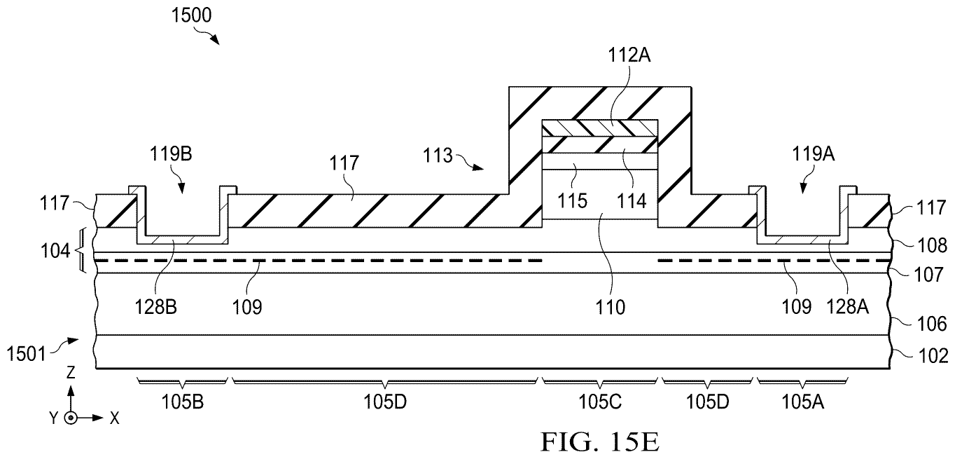

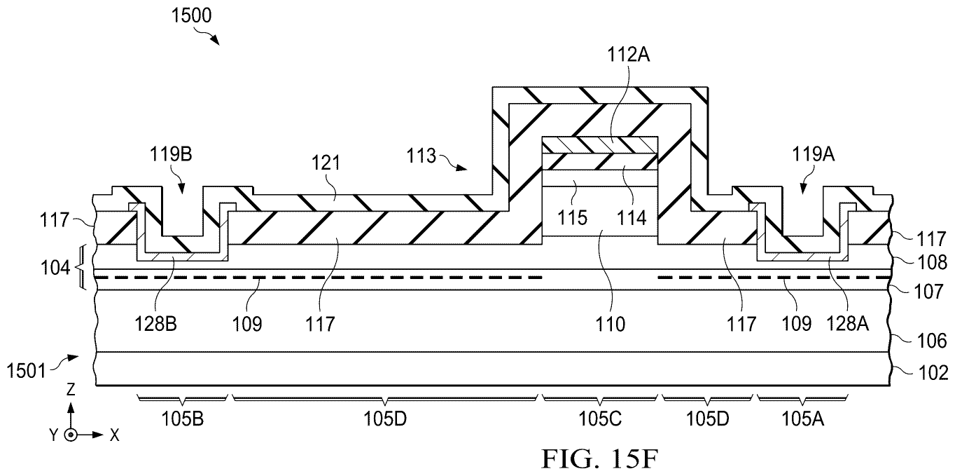

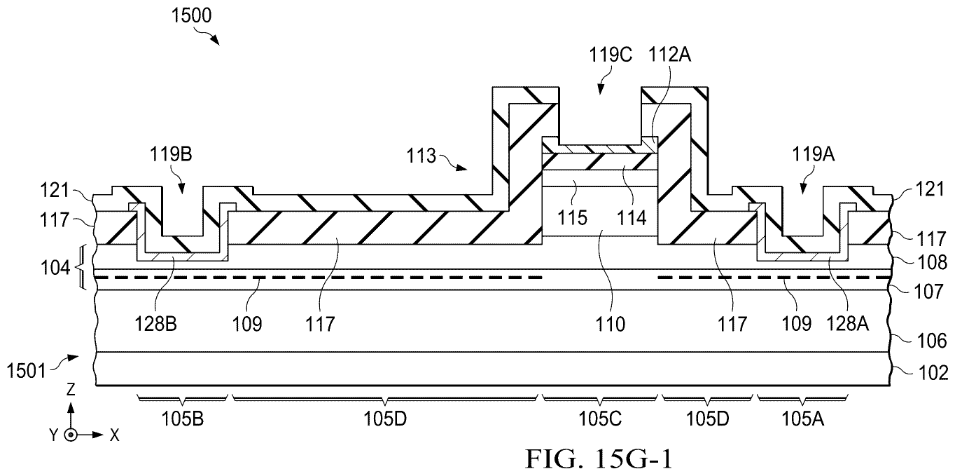

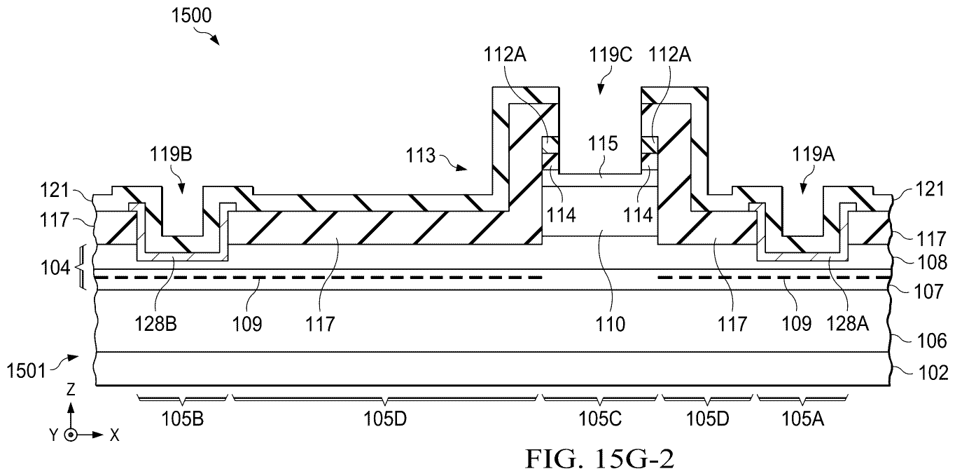

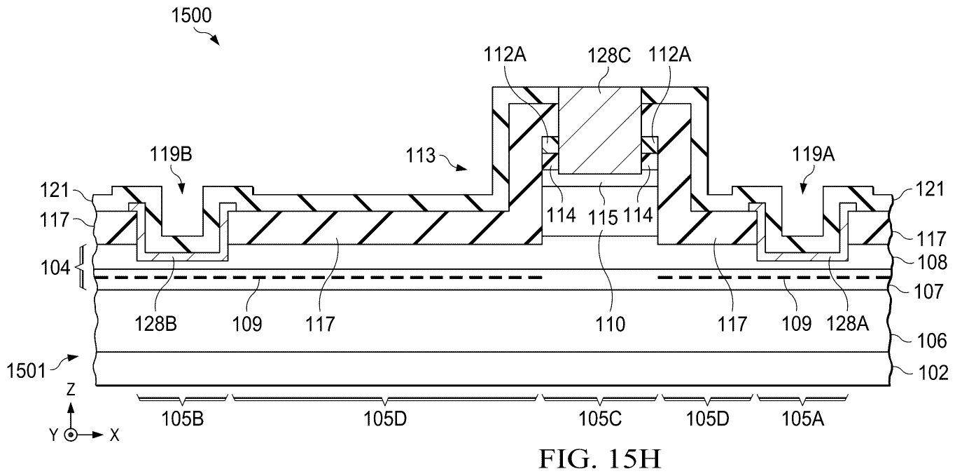

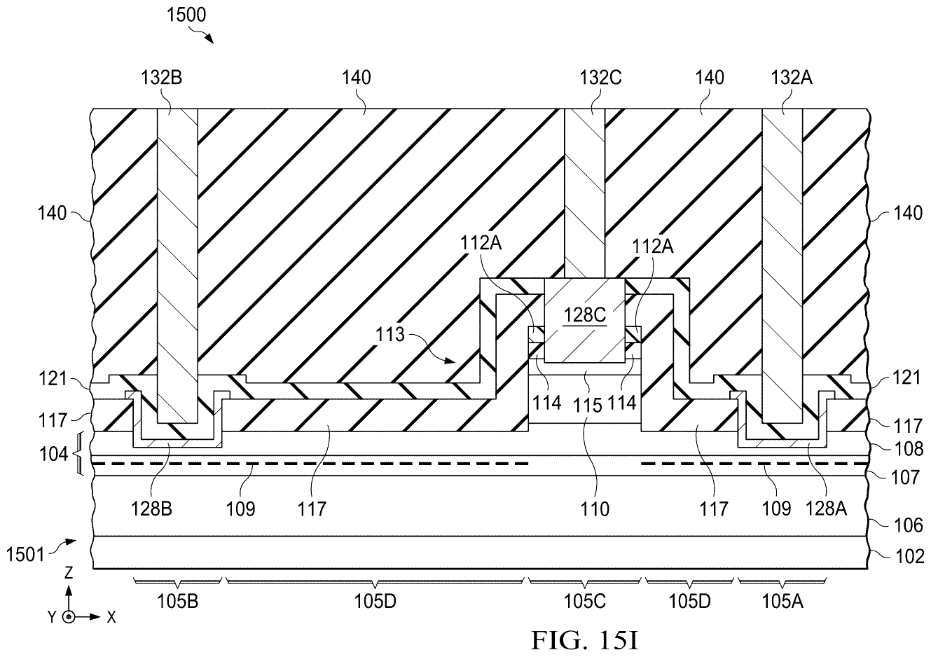

FIGS. 15A-15I depict cross-sectional views of a semiconductor device 1500 including a GaN device 1501 at various stages of a process flow including hybrid etch control for gate stack formation according to an example of the present disclosure. In this example, an EC layer may be formed before forming a gate stack of the GaN device 1501. As illustrated, FIGS. 15A-15I represent a process flow that may include aspects of the process flow set forth in detail above regarding FIGS. 13A-13K. Accordingly, the description set forth above with respect to certain aspects of the process flow shown in FIGS. 13A-13K may be equally applicable to FIGS. 15A-15I with respect to corresponding parts and components except as noted herein.

After forming a III-N cap layer 115 over the p-GaN layer 110 at an intermediate stage shown in FIG. 15A, a dielectric cap layer 114 and an EC layer 112A are formed over the III-N cap layer 115 at a stage shown in FIG. 15B. As described previously, the dielectric cap layer 114 may comprise an LPCVD SiN layer and the EC layer 112A may comprise an ALD layer of a high bandgap material (e.g., a dielectric material with a bandgap energy greater than that of silicon oxide, silicon nitride, etc.), each having respective suitable thicknesses. FIG. 15C depicts a stage where a p-GaN etch is performed for forming a gate stack 113 including the EC layer 112A confined to the gate region 105C. Thereafter, a suitable dielectric layer, e.g., dielectric layer 117, is formed over the semiconductor device 1500 as shown in FIG. 15D. As noted previously, the dielectric layer 117 may be referred to as a first dielectric layer and may comprise an LPCVD SiN layer operable as a passivation layer in some arrangements.

FIG. 15E depicts a contact pattern and metallization stage for forming S/D electrodes 128A/128B in respective contact apertures 119A/119B in the S/D regions 105A/105B using suitable a hybrid etch flow including aspects of the processes set forth above, e.g., as shown in the stages of FIGS. 1F-1G. As there is no EC layer extending over the barrier layer 108 in the S/D regions 105A/105B, a hybrid etch may be omitted in some examples at this stage. Instead, a single etch, e.g., a dry etch or a wet etch, may be used for forming the S/D contact apertures 119A/119B in versions of such examples.

FIG. 15F illustrates a stage where another dielectric layer, e.g., a second dielectric layer 121, is formed over the first dielectric layer 117 in the gate region 105C as well as the access regions 105D. In an example arrangement, the second dielectric layer 121 may extend (e.g., conformally extend) over the conductive sidewalls of the S/D electrodes 128A/128B in the S/D regions 105A/105B. In an example arrangement, the second dielectric layer 121 may comprise a PECVD SiN layer having a suitable thickness, e.g., about 70 nm to 85 nm, as noted previously.

FIGS. 15G-1 and 15G-2 illustrate a stage where a gate contact aperture 119C is formed in the gate stack 113 using a hybrid etch flow similar to the processes set forth above. A dry etch process may be configured to remove material from the first and second dielectric layers 117, 121 and a top portion of the EC layer 112A in the gate stack 113, resulting in a partially formed gate contact aperture landing in the EC layer 112A as shown in FIG. 15G-1. A wet etch process including one or more etch chemistries having a high degree of selectivity between the materials of the EC layer 112A, dielectric cap layer 114 and the III-N cap layer 115, respectively, may be performed thereafter to extend the partially formed gate contact aperture and form a completed gate contact aperture 119C landing in or on the III-N cap layer 115 as shown in FIG. 15G-2. In some arrangements, the wet etch process may be configured to remove material from the III-N cap layer 115 to terminate at a suitable depth in a controllable manner as previously described.

FIG. 15H illustrates a stage where a gate electrode 128C is formed in the gate contact aperture 119C using a suitable gate metal mask and etch process. FIG. 15I depicts a more completely formed semiconductor device 1500 including the GaN device 1501, where source and drain terminals 132A, 132B as well as a gate terminal 132C may be formed for making electrical contact with respective electrodes 128A-128C through an insulator stack 140.

As illustrated in FIG. 15I, the gate electrode 128C may extend through the EC layer 112A and the dielectric cap layer 114, making contact with the III-N cap layer 115. As noted above, S/D electrodes 128A/128B may be formed in a separate etch/metal loop, resulting in having different metals than a metal of the gate electrode 128C in some implementations. Further, S/D electrodes 128A/128B, extending through the dielectric layer 117, may or may not extend into or through the barrier layer 108 (e.g., into the channel layer 107) in some examples as described previously.

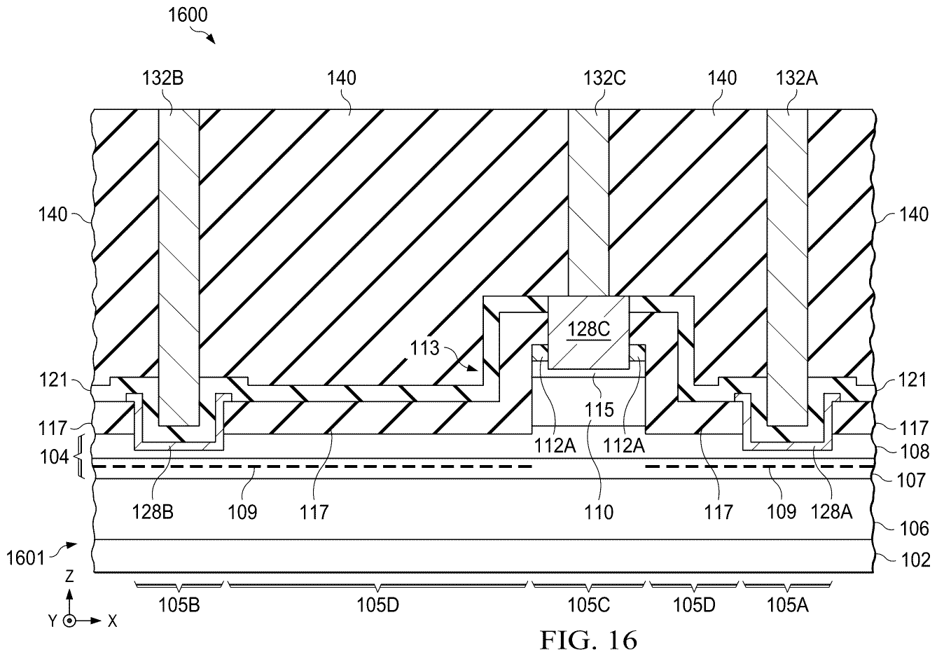

In one variation of the flow set forth above with reference to FIGS. 15A-15I, a dielectric cap layer 114 may be omitted from the gate stack 113 of a semiconductor device 1600 including a GaN device 1601 as shown in FIG. 16. In this example, the wet etch stage of a hybrid etch process for forming the gate contact aperture 119C may be configured to remove a remaining portion of the EC layer 112A and landing in or on the III-N cap layer 115 (e.g., with or without material removal). Accordingly, the gate electrode 128C may extend through the EC layer 112A, making contact with the III-N cap layer 115.

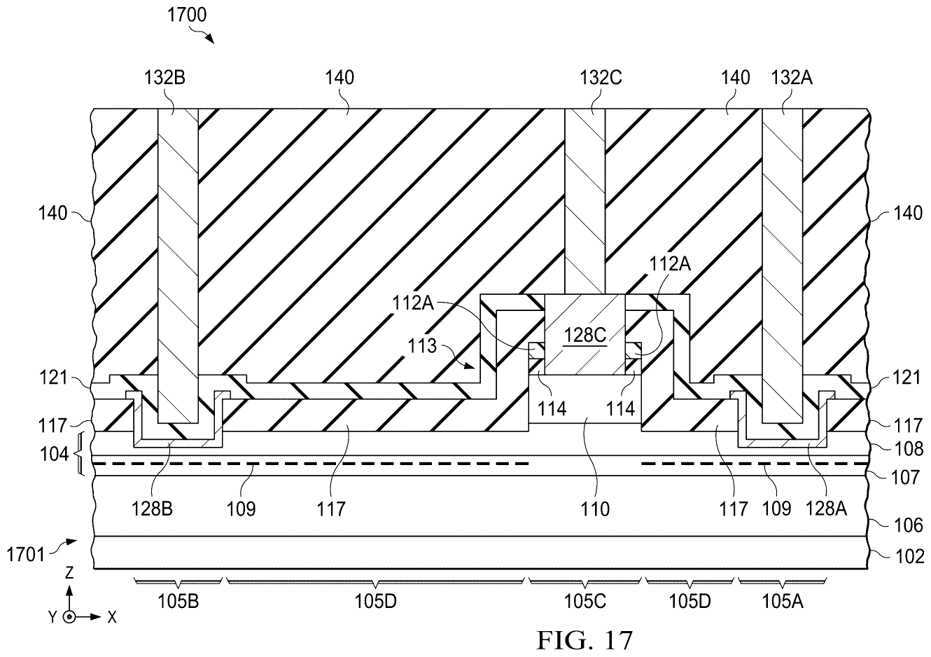

In another variation, a III-N cap layer 115 may be omitted from the gate stack 113 of semiconductor device 1700 including a GaN device 1701 as shown in FIG. 17. In this example, the wet etch stage of a hybrid etch process for forming the gate contact aperture 119C may be configured to remove a remaining portion of the EC layer 112A, the dielectric cap layer 114, and land in or on the p-GaN layer 110. Accordingly, the gate electrode 128C may extend through the EC layer 112A and the dielectric cap layer 114, making contact with the p-GaN layer 110.

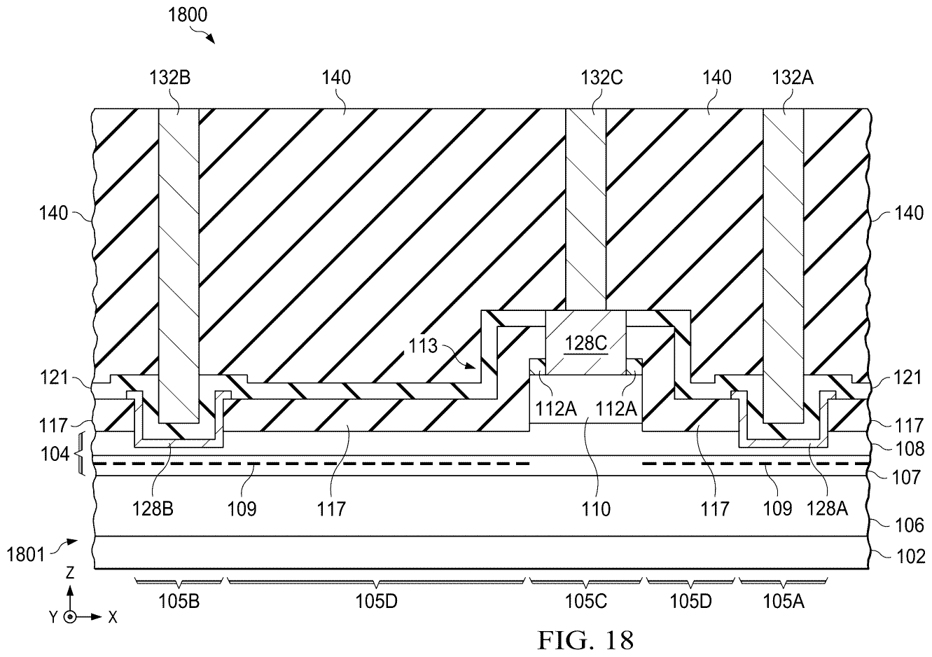

In yet another variation, both dielectric cap layer 114 and III-N cap layer 115 may be omitted from the gate stack 113 of a semiconductor device 1800 including a GaN device 1801 as shown in FIG. 18. In this example, the wet etch stage of a hybrid etch process for forming the gate contact aperture 119C may be configured to remove a remaining portion of the EC layer 112A and land in or on the p-GaN layer 110. Accordingly, the gate electrode 128C may extend through the EC layer 112A, making contact with the p-GaN layer 110.

In the foregoing variations set forth in FIGS. 16-18, the S/D electrodes 128A/128B and the gate electrode 128C may be formed using separate contact etch/metal loops, resulting in S/D electrodes 128A/128B having different metals than a metal of the gate electrode 128C, although it is not a requirement. Accordingly, in some versions of these examples, the S/D electrodes 128A/128B and the gate electrode 128C may have a same metal.

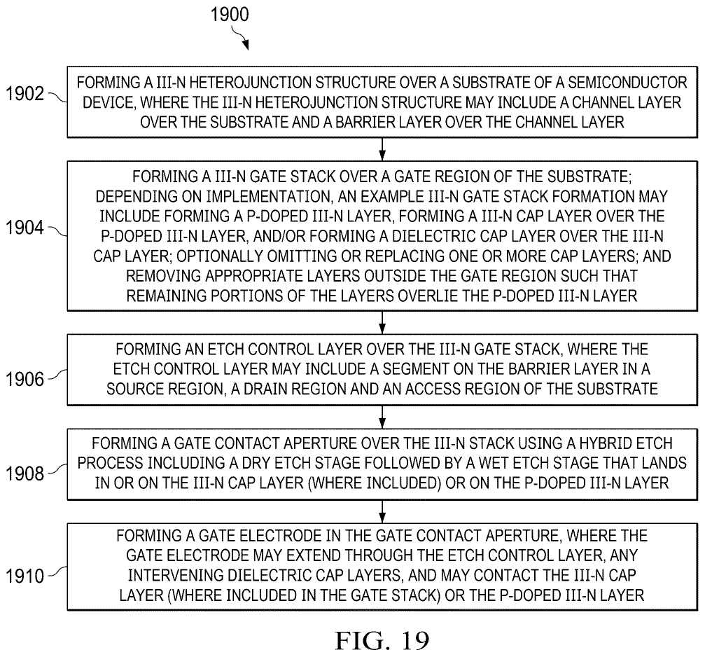

FIG. 19 is a flowchart of a method 1900 of fabricating a semiconductor device using a hybrid etch process flow according to some examples of the present disclosure. At block 1902, a III-N heterojunction structure may be formed over a substrate of the semiconductor device, where the III-N heterojunction structure may include a channel layer over the substrate and a barrier layer over the channel layer. A III-N gate stack may be formed over a gate region of the substrate (block 1904). Depending on implementation, an example III-N gate stack may include a p-doped III-N layer (e.g., p-GaN gate layer) as well as one or more optional cap layers, e.g., a III-N cap layer and/or a dielectric cap layer (e.g., LPCVD). As noted previously, some examples may omit and/or replace the cap layers with additional etch control layers (e.g., ALD layers) in the III-N gate stack. Accordingly, a III-N gate stack may be formed by removing appropriate layers outside the gate region such that remaining portions of the layers overlie the p-doped III-N layer.

At block 1906, an etch control layer may be formed over the III-N gate stack, where the etch control layer may include a segment on the barrier layer in a source region, a drain region and an access region of the substrate. In some examples, the access region may extend laterally from the gate region to the source and drain regions, respectively.

At block 1908, a gate contact aperture may be formed over the III-N stack using a hybrid etch process that includes a dry etch stage followed by a wet etch stage. As described previously, the dry etch stage may be configured to land in the etch control layer. The hybrid etch process at block 1908 may include a wet etch stage configured to remove the remaining portion(s) of the etch control layer and any underlying layers using including one or more etch chemistries. Depending on implementation, the wet etch stage may be configured to stop in or on the III-N cap layer or on the p-doped III-N layer of the gate stack. As noted previously, the etch chemistries applied in different wet etch steps may be selected depending on desired etch selectivities between the etch control layer and the III-N cap layer or p-doped III-N layer as well as any intervening layers.

At block 1910, a gate electrode may be formed in the gate contact aperture, where the gate electrode may extend through the etch control layer, any intervening dielectric cap layers, and may contact the III-N cap layer (where included in the gate stack) or the p-doped III-N layer. As noted previously, the hybrid etch process and gate electrode formation may be integrated in various ways with respect to source/drain electrode formation in an example process flow.

While various examples of the present disclosure have been described above, they have been presented by way of example only and not limitation. Numerous changes to the disclosed examples can be made in accordance with the disclosure herein without departing from the spirit or scope of the disclosure. Thus, the breadth and scope of the present disclosure should not be limited by any of the above described examples. Rather, the scope of the disclosure should be defined in accordance with the claims appended hereto and their equivalents.

For example, in this disclosure and the claims that follow, unless stated otherwise and/or specified to the contrary, any one or more of the layers set forth herein can be formed in any number of suitable ways, such as with spin-on techniques, sputtering techniques (e.g., Magnetron and/or ion beam sputtering), (thermal) growth techniques or deposition techniques such as chemical vapor deposition (CVD), physical vapor deposition (PVD), PECVD, or atomic layer deposition (ALD), etc. As another example, silicon nitride may be a silicon-rich silicon nitride or an oxygen-rich silicon nitride. Silicon nitride may contain some oxygen, but not so much that the materials dielectric constant is substantially different from that of high purity silicon nitride.

Further, in at least some additional or alternative implementations, the functions/acts described in the blocks may occur out of the order shown in the flowcharts. For example, two blocks shown in succession may in fact be executed substantially concurrently or the blocks may sometimes be executed in the reverse order, depending upon the functionality/acts involved. Moreover, the functionality of a given block of the flowcharts and/or block diagrams may be separated into multiple blocks and/or the functionality of two or more blocks of the flowcharts and/or block diagrams may be at least partially integrated. Also, some blocks in the flowcharts may be optionally omitted. Furthermore, although some of the diagrams include arrows on communication paths to show a primary direction of communication, it is to be understood that communication may occur in the opposite direction relative to the depicted arrows. Finally, other blocks may be added/inserted between the blocks that are illustrated.

The order or sequence of the acts, steps, functions, components or blocks illustrated in any of the flowcharts and/or block diagrams depicted in the drawing Figures of the present disclosure may be modified, altered, replaced, customized or otherwise rearranged within a particular flowchart or block diagram, including deletion or omission of a particular act, step, function, component or block. Moreover, the acts, steps, functions, components or blocks illustrated in a particular flowchart may be inter-mixed or otherwise inter-arranged or rearranged with the acts, steps, functions, components or blocks illustrated in another flowchart in order to effectuate additional variations, modifications and configurations with respect to one or more processes for purposes of practicing the teachings of the present disclosure. Likewise, although various examples have been set forth herein, not all features of a particular example are necessarily limited thereto and/or required therefor.

At least some portions of the foregoing description may include certain directional terminology, such as, “upper”, “lower”, “top”, “bottom”, “left-hand”, “right-hand”, “front side”, “backside”, “vertical”, “horizontal”, etc., which may be used with reference to the orientation of some of the Figures or illustrative elements thereof being described. Because components of some examples can be positioned in a number of different orientations, the directional terminology is used for purposes of illustration and is in no way limiting. Likewise, references to features referred to as “first”, “second”, etc., are not indicative of any specific order, importance, and the like, and such references may be interchanged, depending on the context, implementation, etc. In addition, terms such as “over”, “under”, “below”, etc., relative to the spatial orientation of two components does not necessarily mean that one component is immediately or directly over the other component, or that one component is immediately or directly under or below the other component. Further, the features and/or components of examples described herein may be combined with each other unless specifically noted otherwise. With respect to terms indicating a relative degree of variation in a value of a parameter or variable, such as, “around”, “about”, “approximately”, etc., such terms may indicate a percentage or fraction of variation in the value of the parameter or variable, e.g., ±5%, ±10%, etc., depending on the context unless otherwise specified.

Although various implementations have been shown and described in detail, the claims are not limited to any particular implementation or example. None of the above Detailed Description should be read as implying that any particular component, element, step, act, or function is essential such that it must be included in the scope of the claims. Where the phrases such as “at least one of A and B” or phrases of similar import are recited or described, such a phrase should be understood to mean “only A, only B, or both A and B.” Reference to an element in the singular is not intended to mean “one and only one” unless explicitly so stated, but rather “one or more.” In similar fashion, phrases such as “a plurality” or “multiple” may mean “one or more” or “at least one”, depending on the context. All structural and functional equivalents to the elements of the above-described implementations are expressly incorporated herein by reference and are intended to be encompassed by the claims appended below.

What is claimed is:

1. A semiconductor device, comprising:
a substrate including a source region, a gate region, a drain region, and an access region extending laterally from the gate region to the source and drain regions;
a III-N heterojunction structure over the substrate, the III-N heterojunction structure including a channel layer over the substrate and a barrier layer over the channel layer;
a p-doped III-N layer over the barrier layer in the gate region;
a first etch control layer over the p-doped III-N layer;
a dielectric cap layer over the first etch control layer; and
a second etch control layer over the dielectric cap layer, the second etch control layer including a segment on the barrier layer in at least a portion of the access region.

2. The semiconductor device of claim 1, wherein each of the first and second etch control layers is an atomic layer deposition (ALD) layer including at least one of aluminum oxide (Al₂O₃) and aluminum nitride (AlN).

3. The semiconductor device of claim 1, further comprising:
a gate electrode extended through the first etch control layer, the dielectric cap layer, and the second etch control layer, and contacting the p-doped III-N layer.

4. The semiconductor device of claim 1, further comprising:
a III-N cap layer disposed between the p-doped III-N layer and the first etch control layer.

5. The semiconductor device of claim 4, wherein the III-N cap layer is an AlGaN layer.

6. The semiconductor device of claim 4, wherein each of the first and second etch control layers is an atomic layer deposition (ALD) layer including at least one of aluminum oxide (Al₂O₃) and aluminum nitride (AlN).

7. The semiconductor device of claim 4, further comprising:
a gate electrode extended through the first etch control layer, the dielectric cap layer, and the second etch control layer, and contacting the III-N cap layer.

8. A method, comprising:
forming a III-N heterojunction structure over a substrate, the III-N heterojunction structure including a channel layer over the substrate and a barrier layer over the channel layer;
forming a p-doped III-N layer over the barrier layer;
forming a first etch control layer over the p-doped III-N layer;
forming a dielectric cap layer over the first etch control layer;
forming a III-N gate stack in a gate region of the substrate by removing the dielectric cap layer, the first etch control layer and the p-doped III-N layer outside the gate region, the III-N gate stack including remaining portions of the dielectric cap layer and the first etch control layer over the p-doped III-N layer;
forming a second etch control layer over the III-N gate stack, the second etch control layer including a segment on the barrier layer in a source region, a drain region, and an access region of the substrate, the access region extending laterally from the gate region to the source region and the drain region of the substrate; and
forming a gate contact aperture over the III-N gate stack using a hybrid etch process including a dry etch stage followed by a wet etch stage that stops in or on the p-doped III-N layer.

9. The method of claim 8, wherein:
the dry etch stage removes a portion of the second etch control layer and stops in the second etch control layer;
a first step of the wet etch stage removes a remaining portion of the second etch control layer and stops in or on the dielectric cap layer; and
a second step of the wet etch stage removes a remaining portion of the dielectric cap layer and the first etch control layer prior to stopping in or on the p-doped III-N layer.

10. The method of claim 9, further comprising:
before performing the second step of the wet etch stage, forming source and drain contact apertures in the source and drain regions, respectively, using the hybrid etch process including the dry etch stage, the dry etch stage stopping in the segment of the second etch control layer overlying the barrier layer, the dry etch stage followed by the first step of the wet etch stage removing a remaining portion of the segment and stopping in or on the barrier layer; and
forming source and drain electrodes in the source and drain contact apertures, respectively, wherein the source and drain electrodes are of a first metal.

11. The method of claim 10, further comprising:
after forming the source and drain electrodes, performing the second step of the wet etch stage to form the gate contact aperture; and
forming a gate electrode in the gate contact aperture, the gate electrode extending through the second etch control layer, the dielectric cap layer and the first etch control layer, and contacting the p-doped III-N layer, wherein the gate electrode is of a second metal different from the first metal.

12. A method, comprising:
forming a III-N heterojunction structure over a substrate, the III-N heterojunction structure including a channel layer over the substrate and a barrier layer over the channel layer;
forming a p-doped III-N layer over the barrier layer;
forming a III-N cap layer over the p-doped III-N layer;
forming a first etch control layer over the III-N cap layer;
forming a dielectric cap layer over the first etch control layer;
forming a III-N gate stack in a gate region of the substrate by removing the dielectric cap layer, the first etch control layer, the III-N cap layer and the p-doped III-N layer outside the gate region, the III-N gate stack including remaining portions of the dielectric cap layer, the first etch control layer and the III-N cap layer over the p-doped III-N layer;
forming a second etch control layer over the III-N gate stack, the second etch control layer including a segment on the barrier layer in a source region, a drain region, and an access region of the substrate, the access region extending laterally from the gate region to the source region and the drain region of the substrate; and
forming a gate contact aperture over the III-N gate stack using a hybrid etch process including a dry etch stage followed by a wet etch stage that stops in or on the III-N cap layer.

13. The method of claim 12, wherein:
the dry etch stage removes a portion of the second etch control layer and stops in the second etch control layer;
a first step of the wet etch stage removes a remaining portion of the second etch control layer and stops in or on the dielectric cap layer; and
a second step of the wet etch stage removes a remaining portion of the dielectric cap layer and the first etch control layer prior to stopping in or on the III-N cap layer.

14. The method of claim 13, further comprising:
before performing the second step of the wet etch stage, forming source and drain contact apertures in the source and drain regions, respectively, using the hybrid etch process including the dry etch stage, the dry etch stage stopping in the segment of the second etch control layer overlying the barrier layer, the dry etch stage followed by the first step of the wet etch stage removing a remaining portion of the segment and stopping in or on the barrier layer; and
forming source and drain electrodes in the source and drain contact apertures, respectively, wherein the source and drain electrodes are of a first metal.

15. The method of claim 14, further comprising:
after forming the source and drain electrodes, performing the second step of the wet etch stage to form the gate contact aperture; and
forming a gate electrode in the gate contact aperture, the gate electrode extending through the second etch control layer, the dielectric cap layer and the first etch control layer, and contacting the III-N cap layer, wherein the gate electrode is of a second metal different from the first metal.

16. A semiconductor device, comprising:
a substrate including a source region, a gate region, a drain region, and an access region extending laterally from the gate region to the source and drain regions;
a III-N heterojunction structure over the substrate, the III-N heterojunction structure including a channel layer over the substrate and a barrier layer over the channel layer;
a p-doped III-N layer over the barrier layer in the gate region;
a III-N cap layer over the p-doped III-N layer;
an etch control layer over at least a portion of the III-N cap layer, the etch control layer confined to the gate region; and
a gate electrode extended through the etch control layer and contacting the III-N cap layer.

17. The semiconductor device of claim 16, wherein the etch control layer is an atomic layer deposition (ALD) layer comprising at least one of aluminum oxide (Al₂O₃) and aluminum nitride (AlN).

18. The semiconductor device of claim 16, further comprising a dielectric cap layer disposed between the III-N cap layer and the etch control layer, the gate electrode further extended through the dielectric cap layer.

19. A method, comprising:
forming a III-N heterojunction structure over a substrate, the III-N heterojunction structure including a channel layer over the substrate and a barrier layer over the channel layer;
forming a p-doped III-N layer over the barrier layer;
forming a III-N cap layer over the p-doped III-N layer;
forming an etch control layer over the III-N cap layer;
forming a III-N gate stack in a gate region of the substrate by removing the etch control layer, the III-N cap layer and the p-doped III-N layer outside the gate region, the III-N gate stack including remaining portions of the etch control layer and the III-N cap layer over the p-doped III-N layer; and
forming a gate contact aperture over the III-N gate stack using a hybrid etch process including a dry etch stage followed by a wet etch stage that stops in or on the III-N cap layer.

20. The method of claim 19, wherein:
the dry etch stage removes a portion of the etch control layer and stops in the etch control layer; and
the wet etch stage removes a remaining portion of the etch control layer prior to stopping in or on the III-N cap layer.

21. The method of claim 19, further comprising:
forming a dielectric cap layer disposed between the III-N cap layer and the etch control layer, wherein forming the gate contact aperture over the III-N gate stack using the hybrid etch process includes the dry etch stage removing a portion of the etch control layer and stopping in the etch control layer and the wet etch stage removing a remaining portion of the etch control layer and the dielectric cap layer, and stopping in or on the III-N cap layer; and
forming a gate electrode in the gate contact aperture, the gate electrode extending through the etch control layer and the dielectric cap layer, and contacting the III-N cap layer.

22. A semiconductor device, comprising:
a substrate including a source region, a gate region, a drain region, and an access region extending laterally from the gate region to the source and drain regions;
a III-N heterojunction structure over the substrate, the III-N heterojunction structure including a channel layer over the substrate and a barrier layer over the channel layer;
a p-doped III-N layer over the barrier layer in the gate region;
an etch control layer over at least a portion of the p-doped III-N layer, the etch control layer confined to the gate region; and
a gate electrode extended through the etch control layer and contacting the p-doped III-N layer.

23. The semiconductor device of claim 22, wherein the etch control layer is an atomic layer deposition (ALD) layer comprising at least one of aluminum oxide (Al₂O₃) and aluminum nitride (AlN).

24. The semiconductor device of claim 22, further comprising a dielectric cap layer disposed between the p-doped III-N layer and the etch control layer, the gate electrode further extended through the dielectric cap layer.

25. The semiconductor device of claim 24, wherein the dielectric cap layer is a silicon nitride (SiN) layer.

26. A method, comprising:
forming a III-N heterojunction structure over a substrate, the III-N heterojunction structure including a channel layer over the substrate and a barrier layer over the channel layer;
forming a p-doped III-N layer over the barrier layer;
forming an etch control layer over the p-doped III-N layer;
forming a III-N gate stack in a gate region of the substrate by removing the etch control layer and the p-doped III-N layer outside the gate region, the III-N gate stack including a remaining portion of the etch control layer over the p-doped III-N layer; and
forming a gate contact aperture over the III-N gate stack using a hybrid etch process including a dry etch stage followed by a wet etch stage that stops in or on the p-doped III-N layer.

27. The method of claim 26, wherein:
the dry etch stage removes a portion of the etch control layer and stops in the etch control layer; and
the wet etch stage removes a remaining portion of the etch control layer prior to stopping in or on the p-doped III-N layer.

28. The method of claim 26, further comprising:
forming a dielectric cap layer disposed between the p-doped III-N layer and the etch control layer, wherein forming the gate contact aperture over the III-N gate stack using the hybrid etch process includes the dry etch stage removing a portion of the etch control layer and stopping in the etch control layer and the wet etch stage removing a remaining portion of the etch control layer and the dielectric cap layer, and stopping in or on the p-doped III-N layer; and
forming a gate electrode in the gate contact aperture, the gate electrode extending through the etch control layer and the dielectric cap layer, and contacting the p-doped III-N layer.
